(19) United States
(12) Patent Application Publication
(10) Pub. No.: US 2026/0239747 A1
(43) Pub. Date: Aug. 13, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Lin-Yu HUANG, Hsinchu (TW); Jia-Chen CHEN, New Taipei City (TW); Shih-Fan CHEN, Hsinchu City (TW); Sheng-Fu HSU, Hsinchu (TW)

(21) Appl. No.: 19/052,901

(22) Filed: Feb. 13, 2025

(51) Int. Cl. H10D 89/60; H02H 9/02

(52) U.S. Cl. CPC H10D 89/811; H02H 9/025; H10D 89/611; H10D 89/911

(57) ABSTRACT

A semiconductor device includes an electrostatic discharge (ESD) protection device that includes multiple stacked middle voltage and/or low voltage ESD protection circuits including transistors with thinner gate dielectric layers and correspondingly lower threshold voltages than gate dielectric layers and threshold voltages of higher voltage ESD protection circuits. Due to their thinner gate dielectric layers and correspondingly lower threshold voltages, transistors in the middle and/or low voltage ESD protection circuits, including transistors with large active region width values, may fully turn on in response to short charged device model (CDM) pulses. Combined bias voltages of multiple interconnected middle voltage and/or low voltage circuits in a stacked arrangement permits use of the stacked arrangement for high voltage applications. As a result, an ESD protection device that includes multiple stacked middle voltage and/or low voltage circuits may fully dissipate CDM current, leading to improved performance and adequate responses to ESD events.

### BACKGROUND

Electrostatic discharge (ESD) is a concern for semiconductor integrated circuits (ICs). If not handled properly, an ESD event can result in a high voltage that may damage device circuitry of a semiconductor device. To prevent ESD-related damage, a semiconductor device may include an ESD protection circuit. The ESD protection circuit may be operable to divert electrical current away from device circuitry of the semiconductor device during an ESD event, thereby protecting the device circuitry from being damaged by the ESD event.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C are diagrams of an example semiconductor device described herein.

FIGS. 2A-2D are diagrams of an example implementation of forming a semiconductor device described herein.

FIGS. 3A and 3B are diagrams of an example semiconductor device described herein.

FIGS. 4A-4C are diagrams of an example semiconductor device described herein.

FIGS. 5A-5C are diagrams of an example semiconductor device described herein.

FIGS. 6A and 6B are diagrams of an example semiconductor device described herein.

FIGS. 7A-7C are diagrams of an example semiconductor device described herein.

FIG. 8 is a diagram of an example semiconductor device described herein.

FIG. 9 is a diagram of an example semiconductor device described herein.

FIG. 10 is a diagram of an example implementation of a transistor described herein.

FIG. 11 is a diagram of an example implementation of a semiconductor device described herein.

FIG. 12 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An electrostatic discharge (ESD) protection device may be included between regions of a semiconductor device to provide ESD protection for ESD events that might otherwise propagate between the regions of the semiconductor device. For example, an ESD protection device may be included between an input/output (I/O) region and a core integrated circuit (IC) region to protect the core IC region from ESD events that enter the semiconductor device through the I/O region.

Some semiconductor devices include high voltage circuits that are configured to operate at high voltages (e.g., greater than 40 volts, for example). In some cases, ESD protection circuits may be triggered by ESD triggering circuitry that is unable to handle the high voltages of these high voltage circuits and may prematurely trigger ESD protection during normal operation for these high voltage circuits, thereby rendering the high voltage circuits inoperable. As a result, high voltage ESD triggering devices are needed for high voltage circuit applications. A high voltage ESD triggering device may trigger the operation of an ESD protection circuit based on the voltage applied to the high voltage ESD triggering device satisfying a breakdown voltage (BV) of the high voltage ESD triggering device.

Power (e.g., positive supply voltage (VDD)) to ground (e.g., negative supply voltage (VSS)) ESD protection in high voltage applications may be needed for high voltage and/or display products. However, in some high voltage ESD protection circuits including metal-oxide semiconductor (MOS) transistors (e.g., metal-oxide semiconductor field-effect transistors (MOSFETs)), transistor threshold voltages may be high. The high threshold voltages may be due to high voltage ESD protection circuits including MOS transistors with relatively thick gate dielectric (e.g., gate oxide) layers in comparison to gate dielectric layers for MOS transistors in lower voltage ESD protection circuits. As a result, high voltage ESD protection circuits including MOS transistors with large active region width values may not be able to respond to short (e.g., ~1 nanosecond) charged device model (CDM) pulses. For example, due to the high threshold voltages, large width MOS transistors in high voltage ESD protection circuits will not fully turn on and may fail to fully dissipate CDM current in response to an ESD event.

In some implementations described herein, a semiconductor device includes an ESD protection device that includes multiple stacked middle voltage and/or low voltage ESD protection circuits including transistors with thinner gate dielectric layers and correspondingly lower threshold voltages than the gate dielectric layers and threshold voltages of the high voltage ESD protection circuits. Due to their thinner gate dielectric layers and correspondingly lower threshold voltages, transistors in the middle and/or low voltage ESD protection circuits, including transistors with large active region width values, may fully turn on in response to the short (e.g., ~1 nanosecond) CDM pulses. Combined bias voltages of multiple interconnected middle voltage and/or low voltage circuits in a stacked arrangement permits use of the stacked arrangement for high voltage applications. In some cases, the number of middle voltage and/or low voltage circuits can vary based on required bias voltages. In addition, back-to-back (B2B) diodes between middle voltage and/or low voltage circuits may provide additional bias voltages. As a result, an ESD protection device that includes multiple stacked middle voltage and/or low voltage circuits may fully dissipate CDM current, leading to improved performance and adequate responses to ESD events.

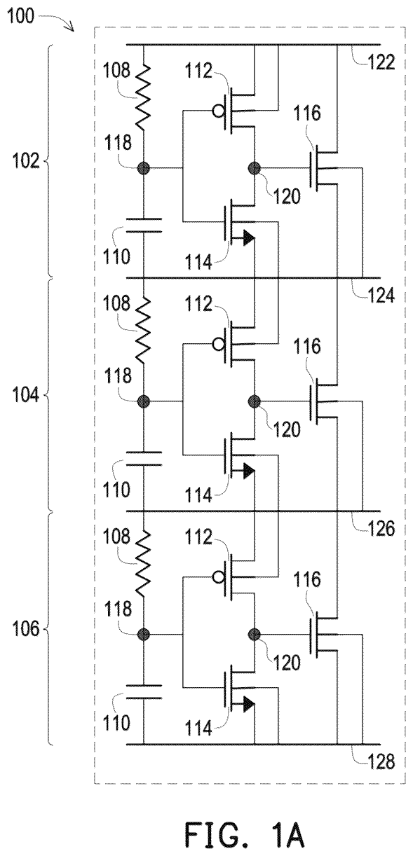

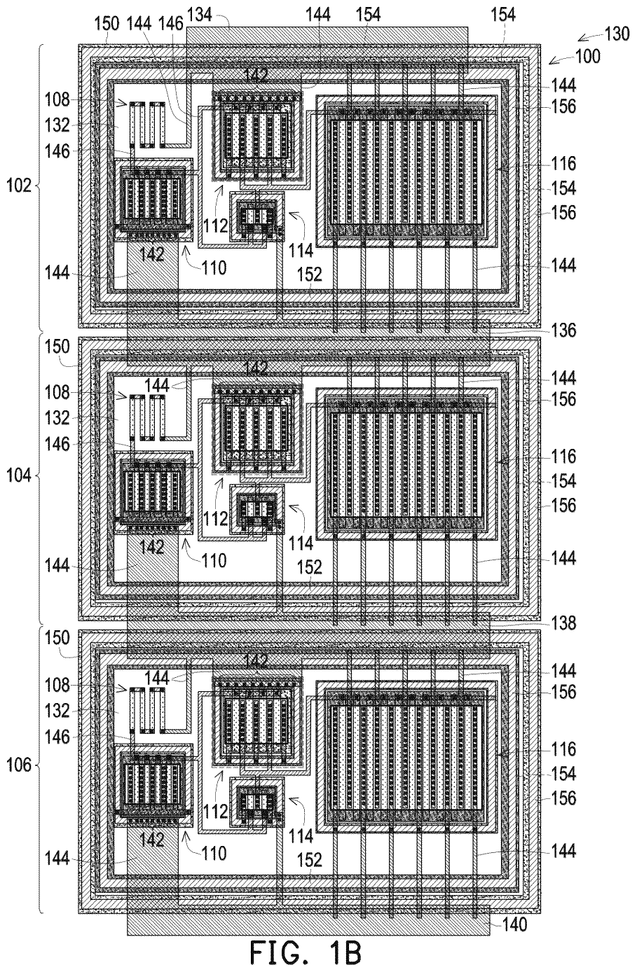

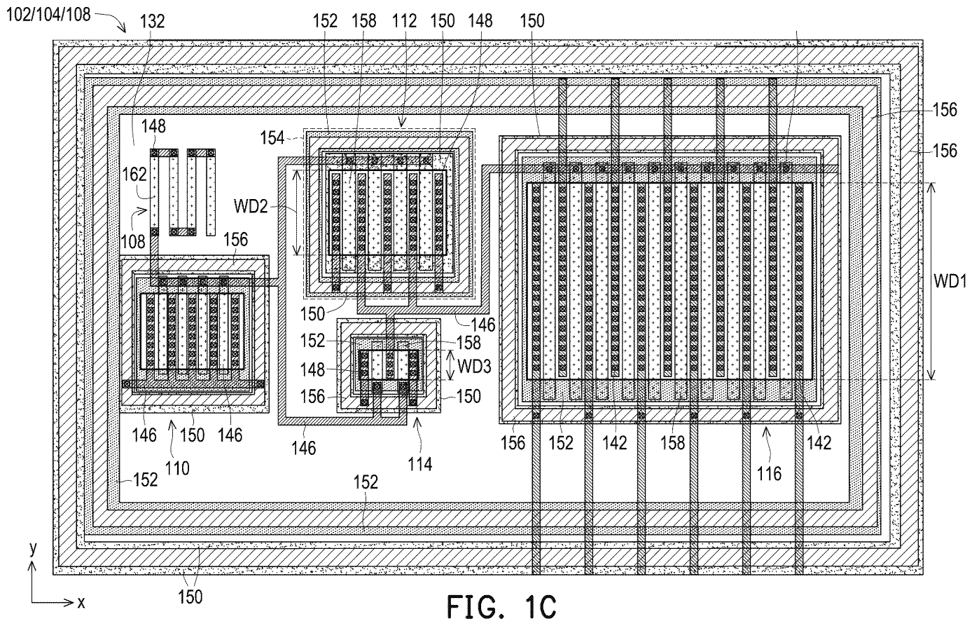

FIG. 1A is a diagram of an example semiconductor device 100 described herein. The semiconductor device 100 may include a logic device (e.g., a processor, a central processing unit (CPU), a graphics processing unit (GPU)), a memory device (e.g., a dynamic random access memory (DRAM) device, a static random access memory (SRAM) device), a display panel device (e.g., a display panel driver including a driver integrated circuit (IC), a line driver IC, a level shifter IC), and/or another type of semiconductor device 100 that includes high voltage semiconductor devices.

An example semiconductor device 100 may include a device circuit, and a plurality of ESD protection circuits 102, 104, and 106, among other types of circuits. In some implementations, the device circuit includes a high voltage device circuit and high voltage transistors. A high voltage transistor may include a high voltage planar transistor, a high voltage fin field effect transistor (finFET), a high voltage nanostructure (e.g., a gate all around (GAA) transistor, a nanowire transistor, a nanosheet transistor, a multi-bridge channel transistor, a nanoribbon transistor), and/or another type of high voltage transistor that is configured to operate at high voltages (e.g., greater than 40 volts, for example).

The ESD protection circuits 102, 104, and 106 may each include a clamp circuit including a grounded-gate metal-oxide semiconductor circuit (e.g., a grounded-gate n-type metal-oxide semiconductor (ggNMOS) circuit) configured to provide ESD protection for the device circuit against high voltage spikes, high voltage surges, and/or other types of high voltage events.

In the example semiconductor device 100, each ESD protection circuit 102, 104, and 106 is a clamp circuit including a resistor 108, a capacitor 110, a gate-drain voltage (VDD) p-type MOSFET (e.g., gdPMOS transistor) 112, a first ggNMOS transistor 114, and a second ggNMOS transistor 116. As explained in more detail herein, the second ggNMOS transistor 116 is a large width FET, having an active region with a larger width than the active region width of the first ggNMOS transistor 114. An “active region” includes, for example, source/drain regions of the transistor and an area between the source/drain regions. “Source/drain region” may refer to a source or a drain, individually or collectively, depending upon the context. A grounded-gate MOSFET or the gate-VDD MOSFET may be a planar transistor, a finFET, a nanostructure (e.g., a GAA transistor, a nanowire transistor, a nanosheet transistor, a multi-bridge channel transistor, a nanoribbon transistor), and/or another type of transistor structure.

A node 118 between the resistor 108 and the capacitor 110 is connected to gates of the gdPMOS transistor 112 and of the first ggNMOS transistor 114. The gdPMOS transistor 112 and the first ggNMOS transistor 114 form an inverter with a high-side p-type transistor (e.g., gdPMOS transistor 112) and a low-side n-type transistor (e.g., ggNMOS transistor 114). A node 120 is connected between source/drain regions of each of the gdPMOS and ggNMOS transistors 112 and 114. The node 120 is connected to a gate of the second ggNMOS transistor 116.

The ESD protection circuit 102 is connected to a supply voltage source 122, providing a positive supply voltage (e.g., drain voltage (VDD)) to the ESD protection circuit 102. The ESD protection circuit 102 and the ESD protection circuit 104 are connected to a first shared voltage source 124, where an output voltage of the ESD protection circuit 102 is provided to the ESD protection circuit 104 as a supply voltage. The ESD protection circuit 104 and the ESD protection circuit 106 are connected to a second shared voltage source 126, where an output voltage of the ESD protection circuit 104 is provided to the ESD protection circuit 106 as a supply voltage. The ESD protection circuit 106 is connected to a ground (e.g., negative supply voltage) voltage source 128.

The ESD protection circuits 102, 104, and 106 are interconnected in a stacked arrangement, where the ESD protection circuits 102, 104, and 106 are connected to each other and connected between the supply voltage source 122 and the ground voltage source 128. In more detail, the gate and a source/drain region of the gdPMOS transistor 112 of the ESD protection circuit 102 are connected to the supply voltage source 122. The gate and a source/drain region of the first ggNMOS transistor 114 of the ESD protection circuit 102 are connected to the first shared voltage source 124. The gate and a source/drain region of the second ggNMOS transistor 116 of the ESD protection circuit 102 are connected to the first shared voltage source 124. The resistor 108 of the ESD protection circuit 102 is connected to the supply voltage source 122, and the capacitor 110 of the ESD protection circuit 102, which is connected in series with resistor 108 of the ESD protection circuit 102, is further connected to the first shared voltage source 124.

The gate and a source/drain region of the gdPMOS transistor 112 of the ESD protection circuit 104 are connected to the first shared voltage source 124. The gate and a source/drain region of the first ggNMOS transistor 114 of the ESD protection circuit 104 are connected to the second shared voltage source 126. The gate and a source/drain region of the second ggNMOS transistor 116 of the ESD protection circuit 104 are connected to the second shared voltage source 126. The resistor 108 of the ESD protection circuit 104 is connected to the first shared voltage source 124, and the capacitor 110 of the ESD protection circuit 104, which is connected in series with resistor 108 of the ESD protection circuit 104, is further connected to the second shared voltage source 126.

A source/drain region of the first ggNMOS transistor 114 of the ESD protection circuit 102 is electrically coupled to a source/drain region of the first ggNMOS transistor 114 of the ESD protection circuit 104 through the first shared voltage source 124. A source/drain region of the second ggNMOS transistor 116 of the ESD protection circuit 102 is electrically coupled to a source/drain region of the second ggNMOS transistor 116 of the ESD protection circuit 104 through the first shared voltage source 124.

The gate and a source/drain region of the gdPMOS transistor 112 of the ESD protection circuit 106 are connected to the second shared voltage source 126. The gate and a source/drain region of the first ggNMOS transistor 114 of the ESD protection circuit 106 are connected to the ground voltage source 128. The gate and a source/drain region of the second ggNMOS transistor 116 of the ESD protection circuit 106 are connected to the ground voltage source 128. The resistor 108 of the ESD protection circuit 106 is connected to the second shared voltage source 126, and the capacitor 110 of the ESD protection circuit 106, which is connected in series with resistor 108 of the ESD protection circuit 106, is further connected to the ground voltage source 128.

A source/drain region of the first ggNMOS transistor 114 of the ESD protection circuit 104 is electrically coupled to a source/drain region of the first ggNMOS transistor 114 of the ESD protection circuit 106 through the second shared voltage source 126. A source/drain region of the second ggNMOS transistor 116 of the ESD protection circuit 104 is electrically coupled to a source/drain region of the second ggNMOS transistor 116 of the ESD protection circuit 106 through the second shared voltage source 126.

In operation, when an input voltage satisfying a threshold to qualify for an ESD event (e.g., a voltage satisfying a BV) is applied to the supply voltage source 122, the capacitor 110 of the ESD protection circuit 102 is shorted. As a result, the gdPMOS transistor 112 of the ESD protection circuit 102 is turned on, while the first ggNMOS transistor 114 of the ESD protection circuit 102 is off. The gdPMOS transistor 112 of the ESD protection circuit 102 is turned on because the gate-to-source voltage (Vgs) resulting from the input voltage to the supply voltage source 122 is greater than the threshold voltage (Vt) of the gdPMOS transistor 112 of the ESD protection circuit 102. The activation of the gdPMOS transistor 112 of the ESD protection circuit 102 causes the gate of the second ggNMOS transistor 116 of the ESD protection circuit 102 to receive a voltage approximately equal to the input voltage to the supply voltage source 122. As a result, similar to the operation of the gdPMOS transistor 112 of the ESD protection circuit 102, the second ggNMOS transistor 116 of the ESD protection circuit 102 is turned on because the Vgs is greater than the Vt of the second ggNMOS transistor 116 of the ESD protection circuit 102.

Due to the activation of the second ggNMOS transistor 116 of the ESD protection circuit 102, dissipated voltage corresponding to the voltage inputted to the supply voltage source 122 is transmitted from the source/drain region of the second ggNMOS transistor 116 of the ESD protection circuit 102 to the first shared voltage source 124, which activates the ESD protection circuit 104 in a similar manner to the ESD protection circuit 102. In more detail, the dissipated voltage applied to the first shared voltage source 124 causes the capacitor 110 of the ESD protection circuit 104 to be shorted. As a result, the gdPMOS transistor 112 of the ESD protection circuit 104 is turned on, while the first ggNMOS transistor 114 of the ESD protection circuit 104 is off. The gdPMOS transistor 112 of the ESD protection circuit 104 is turned on because the Vgs resulting from the dissipated voltage inputted to the first shared voltage source 124 is greater than the Vt of the gdPMOS transistor 112 of the ESD protection circuit 104. The activation of the gdPMOS transistor 112 of the ESD protection circuit 104 causes the gate of the second ggNMOS transistor 116 of the ESD protection circuit 104 to receive a voltage approximately equal to the dissipated voltage. As a result, the second ggNMOS transistor 116 of the ESD protection circuit 104 is turned on because the Vgs is greater than the Vt of the second ggNMOS transistor 116 of the ESD protection circuit 104.

Due to the activation of the second ggNMOS transistor 116 of the ESD protection circuit 104, further dissipated voltage corresponding to a portion of the original voltage inputted to the supply voltage source 122 is transmitted from the source/drain region of the second ggNMOS transistor 116 of the ESD protection circuit 104 to the second shared voltage source 126, which activates the ESD protection circuit 106 in a similar manner to the ESD protection circuits 102 and 104. In more detail, the dissipated voltage applied to the second shared voltage source 126 causes the capacitor 110 of the ESD protection circuit 106 to be shorted. As a result, the gdPMOS transistor 112 of the ESD protection circuit 106 is turned on, while the first ggNMOS transistor 114 of the ESD protection circuit 106 is off. The gdPMOS transistor 112 of the ESD protection circuit 106 is turned on because the Vgs resulting from the dissipated voltage inputted to the second shared voltage source 126 is greater than the Vt of the gdPMOS transistor 112 of the ESD protection circuit 106. The activation of the gdPMOS transistor 112 of the ESD protection circuit 106 causes the gate of the second ggNMOS transistor 116 of the ESD protection circuit 106 to receive a voltage approximately equal to the dissipated voltage. As a result, the second ggNMOS transistor 116 of the ESD protection circuit 106 is turned on because the Vgs is greater than the Vt of the second ggNMOS transistor 116 of the ESD protection circuit 106. Due to the activation of the second ggNMOS transistor 116 of the ESD protection circuit 106, a final dissipated voltage corresponding to a portion of the original voltage inputted to the supply voltage source 122 is transmitted from the source/drain region of the second ggNMOS transistor 116 of the ESD protection circuit 106 to the ground voltage source 128.

The multiple stacked ESD protection circuits 102, 104, and 106 may each be biased at a lower voltage than a single high voltage ESD protection circuit. In a non-limiting example, each of the multiple stacked ESD protection circuits 102, 104, and 106 may be biased in a range of approximately 8 volts to approximately 10 volts instead of a single high voltage ESD circuit being biased at approximately 24 to approximately 30 volts, or at a higher voltage. As a result of the lower bias voltage for each circuit, the ESD protection circuits 102, 104, and 106 may include transistors with thinner gate dielectric layers and correspondingly lower threshold voltages than the gate dielectric layers and threshold voltages of the transistors of the high voltage ESD protection circuits. Due to their thinner gate dielectric layers and correspondingly lower threshold voltages, the transistors in the ESD protection circuits 102, 104, and 106, including the second ggNMOS transistors 116 with large active region width values, may fully turn on in response to short (e.g., ~1 nanosecond) CDM pulses. Combined bias voltages of multiple interconnected ESD protection circuits 102, 104, and 106 in a stacked arrangement permits use of the stacked arrangement for high voltage applications. For example, the total of the bias voltages of multiple ESD protection circuits (e.g., ESD protection circuits 102, 104, and 106) may be equal to the bias voltage of a single high voltage ESD protection circuit, so that the multiple interconnected ESD protection circuits may be used in place of a single high voltage

ESD protection circuit to fully dissipate CDM current, leading to improved performance and adequate responses to ESD events. As explained in more detail herein, the number of ESD protection circuits can vary based on individual bias voltage values of each ESD protection circuit, and a required total bias voltage. In some implementations, the bias voltages of each of the ESD protection circuits in a stacked arrangement are equal, or substantially equal, to each other.

Depending upon a required total bias value of the plurality of ESD protection circuits (e.g., ESD protection circuits 102, 104, and 106), the number of ESD protection circuits in a stacked arrangement may vary. For example, in some implementations, the number of ESD protection circuits in a stacked arrangement may vary from 3 to 6.

FIG. 1B is a diagram of an example implementation 130 of a layout of the semiconductor device 100 described herein. FIG. 1C illustrates an enlarged view of the layout of an ESD protection circuit 102, 104, or 106. As shown in FIG. 1B, each ESD protection circuit 102, 104, and 106 is on a substrate 132. The substrate 132 may include silicon (Si) (e.g., a silicon substrate), a silicon layer or another type of semiconductor layer, a material including silicon, a III-V compound semiconductor material such as gallium arsenide (GaAs), a silicon on insulator (SOI) substrate, or another type of semiconductor material. The resistor 108, the capacitor 110, the gdPMOS transistor 112, the first ggNMOS transistor 114, and the second ggNMOS transistor 116 of each ESD protection circuit 102, 104, and 106 may be formed on a substrate 132.

The semiconductor device 100 may include an interconnect layer including a plurality of conductive structures 134, 136, 138, 140, 142, 144, 146, and 148 (e.g., electrically conductive structures) formed in one or more dielectric layers on a substrate 132. The dielectric layers may include backend dielectric layers (e.g., interlayer dielectric (ILD) layers, intermetal dielectric (IMD) layers) and etch stop layers (ESLs)) that are arranged in a direction that is approximately orthogonal to the substrate 132. The dielectric layers may each include various dielectric materials, such as an oxide (e.g., a silicon oxide (SiOₓ) and/or another oxide material), an undoped silicate glass (USG), a boron-containing silicate glass (BSG), a fluorine-containing silicate glass (FSG), an extreme low dielectric constant (ELK) dielectric material having a dielectric constant that is less than approximately 2.5, a silicon nitride (SiₓN_{y}), silicon carbide (SiC), silicon oxynitride (SiON), and/or another suitable dielectric material.

The conductive structures 134, 136, 138, 140, 142, 144, 146, and/or 148 are electrically coupled and/or physically coupled to the resistor 108, the capacitor 110, the gdPMOS transistor 112, the first ggNMOS transistor 114, and/or the second ggNMOS transistor 116 of each ESD protection circuit 102, 104, and 106, and/or other structures of the semiconductor device 100. Moreover, the conductive structures 134, 136, 138, 140, 142, 144, 146, and/or 148 may be electrically interconnected together in the interconnect layer. The conductive structures 134, 136, 138, 140, 142, 144, 146, and/or 148 correspond to circuit routing that enables signals and/or power to be provided to and/or from components of the ESD protection circuits 102, 104, and 106. The conductive structures 134, 136, 138, 140, 142, 144, 146, and 148 may include a combination of conductive structures that extend primarily horizontally in the interconnect layer (e.g., trenches, conductive lines) and that are interconnected by interconnect structures (e.g., vias) that extend primarily vertically in the interconnect layer. The conductive structures 134, 136, 138, 140, 142, 144, 146, and 148 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

The conductive interconnects of the interconnect layer may be arranged in a vertical manner to facilitate electrical signals and/or power to be routed between integrated circuit devices in different layers. The conductive structures 134, 136, 138, 140, 142, 144, 146, and 148 may be arranged in alternating layers of metallization layers (referred to as “M” layers) and via layers (referred to as “V” layers). Each metallization layer may include one or more conductive structures laterally arranged in the interconnect layer, and each via layer may include one or more interconnect structures that interconnect the metallization layers in the interconnect layer. As an example, a metal-0 (M0) layer may be located at the bottom of the interconnect layer, a via-0 (V0) layer may be located above and coupled to the M0 layer in the interconnect layer, a metal-1 (M1) layer may be located above and coupled to the V0 layer in the interconnect layer, a via-1 (V1) layer may be located above and coupled to the M1 layer in the interconnect layer, a metal-2 (M2) layer may be located above and electrically coupled to the V1 layer in the interconnect layer, and so on.

For example, the conductive structures 134, 136, 138 and 140 may be part of one or more metallization layers and may respectively correspond to the supply voltage source 122, the first shared voltage source 124, the second shared voltage source 126, and the ground voltage source 128. The conductive structures 144 may be metallization layer structures connecting the resistor 108, the capacitor 110, the gdPMOS transistor 112, the first ggNMOS transistor 114, and/or the second ggNMOS transistor 116 of each ESD protection circuit 102, 104, and/or 106 to the conductive structures 134, 136, 138 and/or 140. The conductive structures 142 may be interconnect structures (e.g., vias) connecting the resistor 108, the capacitor 110, the gdPMOS transistor 112, the first ggNMOS transistor 114, and/or the second ggNMOS transistor 116 of each ESD protection circuit 102, 104, and/or 106 to the conductive structures 144.

In more detail, the gate and a source/drain region of the gdPMOS transistor 112 of the ESD protection circuit 102 are connected to the conductive structure 134 through conductive structures 142 and 144. The gate and a source/drain region of the first ggNMOS transistor 114 of the ESD protection circuit 102 are connected to the conductive structure 136 through conductive structures 142 and 144. The gate and a source/drain region of the second ggNMOS transistor 116 of the ESD protection circuit 102 are connected to the conductive structure 136 through conductive structures 142 and 144. The resistor 108 of the ESD protection circuit 102 is connected to the conductive structure 134 through conductive structures 142 and 144, and the capacitor 110 of the ESD protection circuit 102 is connected to the conductive structure 134 through conductive structures 142 and 144.

The gate and a source/drain region of the gdPMOS transistor 112 of the ESD protection circuit 104 are connected to the conductive structure 136 through conductive structures 142 and 144. The gate and a source/drain region of the first ggNMOS transistor 114 of the ESD protection circuit 104 are connected to the conductive structure 138 through conductive structures 142 and 144. The gate and a source/drain region of the second ggNMOS transistor 116 of the ESD protection circuit 104 are connected to the conductive structure 138 through conductive structures 142 and 144. The resistor 108 of the ESD protection circuit 104 is connected to the conductive structure 136 through conductive structures 142 and 144, and the capacitor 110 of the ESD protection circuit 104 is connected to the conductive structure 138 through conductive structures 142 and 144.

A source/drain region of the first ggNMOS transistor 114 of the ESD protection circuit 102 is electrically coupled to a source/drain region of the first ggNMOS transistor 114 of the ESD protection circuit 104 through the conductive structures 136, 142 and 144. A source/drain region of the second ggNMOS transistor 116 of the ESD protection circuit 102 is electrically coupled to a source/drain region of the second ggNMOS transistor 116 of the ESD protection circuit 104 through the conductive structures 136, 142 and 144.

The gate and a source/drain region of the gdPMOS transistor 112 of the ESD protection circuit 106 are connected to the conductive structure 138 through conductive structures 142 and 144. The gate and a source/drain region of the first ggNMOS transistor 114 of the ESD protection circuit 106 are connected to the conductive structure 140 through conductive structures 142 and 144. The gate and a source/drain region of the second ggNMOS transistor 116 of the ESD protection circuit 106 are connected to the conductive structure 140 through conductive structures 142 and 144. The resistor 108 of the ESD protection circuit 106 is connected to the conductive structure 138 through conductive structures 142 and 144, and the capacitor 110 of the ESD protection circuit 106 is connected to the conductive structure 140 through conductive structures 142 and 144.

A source/drain region of the first ggNMOS transistor 114 of the ESD protection circuit 104 is electrically coupled to a source/drain region of the first ggNMOS transistor 114 of the ESD protection circuit 106 through the conductive structures 138, 142 and 144. A source/drain region of the second ggNMOS transistor 116 of the ESD protection circuit 104 is electrically coupled to a source/drain region of the second ggNMOS transistor 116 of the ESD protection circuit 106 through the conductive structures 138, 142 and 144.

The conductive structures 146 may be metallization layer structures connecting the resistor 108, the capacitor 110, the gdPMOS transistor 112, the first ggNMOS transistor 114, and/or the second ggNMOS transistor 116 of each ESD protection circuit 102, 104, and/or 106 to each other. The conductive structures 148 may be interconnect structures (e.g., vias) extending between the conductive structures 146 and portions of the resistor 108, the capacitor 110, the gdPMOS transistor 112, the first ggNMOS transistor 114, and/or the second ggNMOS transistor 116 of each ESD protection circuit 102, 104, and/or 106. For example, for an ESD protection circuit 102, 104 or 106, a resistor 108 may be electrically coupled to the capacitor 110 through the conductive structures 146 and 148. The resistor 108 and/or capacitor 110 may be electrically coupled to the gates of the gdPMOS transistor 112 and of the first ggNMOS transistor 114 through the conductive structures 146 and 148. Source/drain regions of the gdPMOS transistor 112 and of the first ggNMOS transistor 114 may be electrically coupled to the gate of the second ggNMOS transistor 116 through the conductive structures 146 and 148.

FIGS. 1B and 1C further illustrate a plurality of doped regions that are included in the substrates 132. For example, the ESD protection circuits 102, 104, and 106 may include a plurality of p+ regions 150, n+ regions 152, n-doped wells 154 and p-doped wells (not labeled) in remaining portions of the substrates 132 (areas that are not enclosed by the dotted lines indicating the n-doped wells 154 are p-doped wells). The p-doped wells may be regions of a substrate 132 that are doped with one or more p-type dopants, such as boron (B), gallium (Ga), and/or indium (In), among other examples. The n-doped wells 154 may be regions of a substrate 132 that are doped with one or more n-type dopants, such as phosphorous (P), arsenic (As), bismuth (Bi), and/or antimony (Sb), among other examples. Including the p-doped wells may reduce on resistance (Rₒₙ) for the ESD protection circuits 102, 104, and 106. Including the n-doped wells 154 may reduce on resistance (Rₒₙ) for the ESD protection circuits 102, 104, and 106.

The p+ regions 150 (e.g., p-type regions) may be regions of the substrate 132 that are doped with one or more p-type dopants, such as boron (B), gallium (Ga), and/or indium (In), among other examples. The n+ regions 152 (e.g., n-type regions) may be regions of the substrate 132 that are doped with one or more n-type dopants, such as phosphorous (P), arsenic (As), bismuth (Bi), and/or antimony (Sb), among other examples.

The p-doped wells and the p+ regions 150 may have different dopant concentrations. For example, the dopant concentration in the p+ regions 150 may be greater relative to a dopant concentration in the p-doped wells.

The n-doped wells 154 and the n+ regions 152 may have different dopant concentrations. For example, the dopant concentration in the n+ regions 152 may be greater relative to a dopant concentration in the n-doped wells 154.

FIGS. 1B and 1C further illustrate active area defining regions 156, in which active regions of different components (e.g., transistors) are defined. For example, active regions of a device such as a transistor include parts of a substrate encompassing the source/drain regions and the area between the source/drain regions. Source/drain regions of the gdPMOS transistor 112, the first ggNMOS transistor 114, and the second ggNMOS transistor 116 are within the active area defining regions 156. The conductive structures 144 and 146 extend into the active regions to connect to the source/drain regions through the conductive structures 142 and 148. Gate structures 158 are further illustrated in the gdPMOS transistor 112, the first ggNMOS transistor 114, and the second ggNMOS transistor. A gate structure 158 may include a gate dielectric layer on the substrate 132. The gate dielectric layer may be included between the substrate 132 and a gate electrode. The gate dielectric layer may include one or more dielectric materials, such as a low dielectric constant (low-k) dielectric material (e.g., silicon oxide (SiOₓ such as SiO₂)), a high dielectric constant (high-k) dielectric material (e.g., hafnium oxide (HfOₓ such as HfO₂)), and/or another suitable gate dielectric material. The gate electrode may include one or more metal materials such as tungsten (W), cobalt (Co), ruthenium (Ru), and/or titanium (Ti), among other examples. Additionally and/or alternatively, the gate electrode may include one or more work function metal layers for tuning the work function of the gate electrode.

As shown in FIG. 1C, in some implementations, a “width” (WD) of a transistor is the dimension in the y-direction of the active region. In addition, a “total width” of a transistor may be defined according to the formula (1):

$$Total Width = WD * Finger Quantity \qquad ( 1 )$$

where “finger” refers to a gate structure, and “finger quantity” refers to a quantity of fingers in an active region of a transistor. For example, in the case of the second ggNMOS transistor 116 in FIG. 1C, the total width may be WD1*10, since the number of gate structures 158 for the second ggNMOS transistor 116 is 10. In some implementations, the width WD1 of the second ggNMOS transistor 116 may be included in the range of approximately 1000 microns to approximately 10000 microns. If the width WD1 is less than approximately 1000 microns, the on resistance (Rₒₙ) of the second ggNMOS transistor 116 may be relatively high and lead to reduced operating efficiency for the ESD protection circuit 102, 104, or 106. If the width WD1 is greater than approximately 10000 microns, the size of the ESD protection circuit 102, 104, or 106 may increase, thereby reducing device density in the semiconductor device. However, other values for the range are within the scope of the present disclosure.

In some implementations, the width WD2 of the gdPMOS transistor 112 may be included in the range of approximately 30 microns to approximately 500 microns. If the width WD2 is less than approximately 30 microns, driving of the gdPMOS transistor 112 may be too weak and lead to weak turn on capability of the second ggNMOS transistor 116 during an ESD event. If the width WD2 is greater than approximately 500 microns, driving of the gdPMOS transistor 112 may be too strong and lead to high leakage current for the second ggNMOS transistor 116 during normal operation. However, other values for the range are within the scope of the present disclosure.

In some implementations, the width WD3 of the first ggNMOS transistor 114 may be included in the range of approximately 5 microns to approximately 100 microns. If the width WD3 is less than approximately 5 microns, driving of the first ggNMOS transistor 114 may be too weak and lead to high leakage current for the second ggNMOS transistor 116 during normal operation. If the width WD3 is greater than approximately 100 microns, driving of the first ggNMOS transistor 114 may be too weak and lead to weak turn on capability of the second ggNMOS transistor 116 during an ESD event. However, other values for the range are within the scope of the present disclosure.

As shown in FIG. 1C, the capacitor 110 may include a plurality of capacitor electrodes 160 (e.g., bottom and top electrodes). In some implementations, the capacitor structure is designed to achieve a small lateral footprint, and may include a metal-insulator-metal (MIM) layer stack in which bottom electrode layers and top electrode layers are arranged in an alternating manner and separated by insulator layers. In some cases, the size of the capacitor 110 may be increased in a vertical direction such that the capacitor 110 extends through a plurality of layers in a semiconductor device 100 to form a deep trench capacitor (DTC). A DTC is a type of capacitor structure that is formed in a deep trench in a semiconductor device such that the electrode layers and insulator layers extend along, and conform to, a profile of the deep trench. This enables the area of the conductive electrode layers to be increased (which increases the capacitance) with minimal increase in the lateral size of the capacitor structure. The trench of a DTC structure is typically formed to have a high aspect ratio between the depth of the trench and the width of the trench.

The resistor 108 of the ESD protection circuits 102, 104, and 106 may conduct large current surges during an ESD event, allowing the capacitor 110 to charge quickly and so that voltage may be clamped to a level to prevent damage to a device circuit. The resistor 108 may limit current to control a rate at which the capacitor 110 charges during an ESD event. In some implementations, the resistive structure 162 of the resistor 108 may include thick film materials, thin film materials, and/or metal-oxide materials. Some example materials for the resistive structure 162 may include titanium nitride (TiN) and/or silicon chromium (SiCr). The resistor 108 may be connected to the capacitor 110 through conductive structures 148 (e.g., interconnect structures) connected to the resistive structure 162 and conductive structures 146 (e.g., metallization level structures) between the resistor 108 and the capacitor 110.

As indicated above, FIGS. 1A-1C are provided as examples. Other examples may differ from what is described with regard to FIGS. 1A-1C.

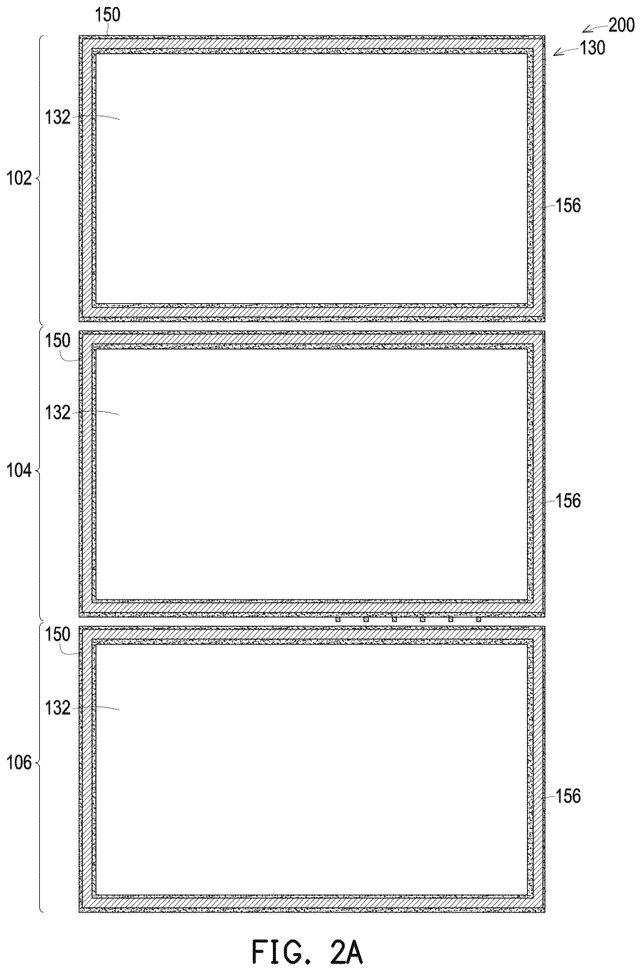

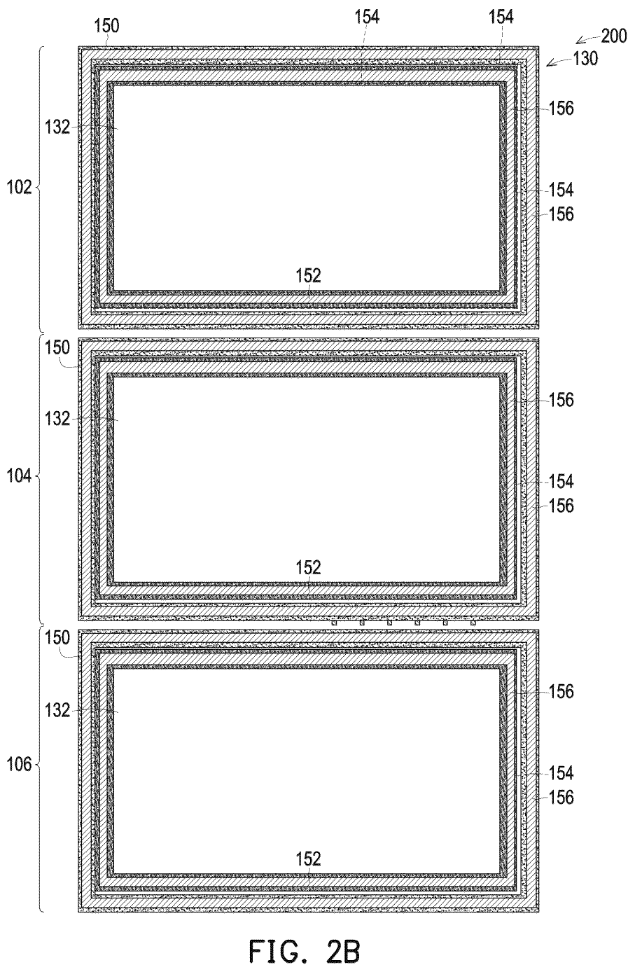

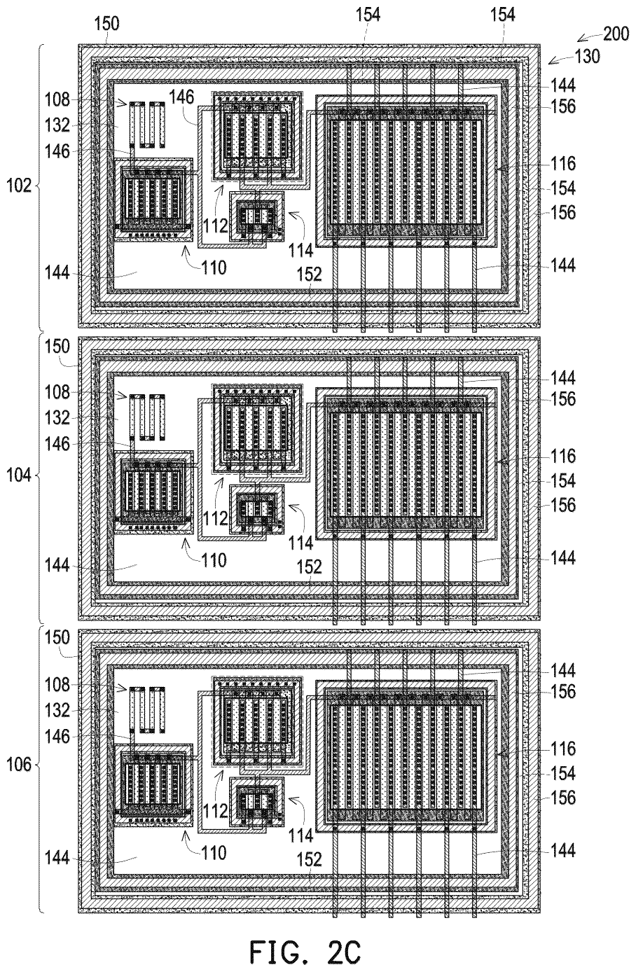

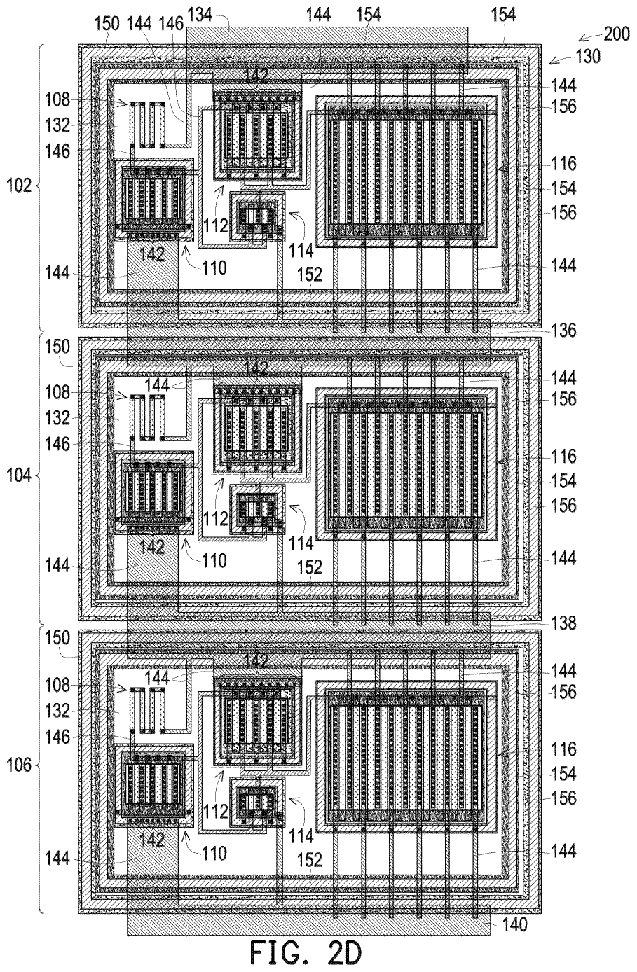

FIGS. 2A-2D are diagrams of an example implementation 200 of forming a semiconductor device 100 described herein. In some implementations, one or more semiconductor processing tools may be used to perform one or more of the operations described in connection with the example implementation 200, such as a deposition tool, an exposure tool, a developer tool, an etch tool, a planarization tool, a plating tool, and/or another type of semiconductor processing tool.

Turning to FIG. 2A, substrates 132 may be provided. The substrate 132 may be provided as a semiconductor wafer, a semiconductor die, and/or another type of semiconductor substrate. In some implementations, the substrate 132 may be a doped substrate, such as a semiconductor substrate that is doped with one or more p-type dopants, a semiconductor substrate that is doped with one or more n-type dopants, and/or another type of doped substrate. In some implementations, the substrate 132 has a bulk resistivity (or volumetric resistivity) that is included in a range of approximately 1 ohm-centimeter to approximately 100 ohm-centimeters. However, other values for the range are within the scope of the present disclosure.

One or more p+ implantation operations may be performed to form p+ regions 150 around the active area defining region 156. In some implementations, an ion implantation tool performs one or more implantation operations to form the p+ regions 150 in the substrate 132 by performing an ion implantation operation to implant ions (e.g., p-type ions) into the substrate 132 to form the p+ regions 150. The ion implantation tool may direct an ion beam toward the substrate 132 such that the ions are implanted below the surface of the substrate 132 to dope the substrate 132. An implantation mask may be formed on the substrate 132, and a pattern formed in the implantation mask may be used to form the p+ regions 150.

As shown in FIG. 2B, one or more well implantation operations may be performed to form n-doped wells 154 in the substrate 132. The n-doped wells 154 may be formed below the surface of the substrate 132.

In some implementations, an ion implantation tool performs the one or more well implantation operations to form the n-doped wells 154 in the substrate 132 by performing an ion implantation operation to implant ions (e.g., n-type ions) into the substrate 132 to form the n-doped wells 154. The ion implantation tool may direct an ion beam toward the substrate 132 such that the ions are implanted below the surface of the substrate 132 to dope the substrate 132. An implantation mask may be formed on the substrate 132, and a pattern formed in the implantation mask may be used to form the n-doped wells 154.

One or more n+ implantation operations may be performed to form n+ regions 152 in the substrate 132. The n+ regions 152 may be formed in the n-doped wells 154. In this way each n+ region 152 may be included within an associated n-doped well 154.

In some implementations, an ion implantation tool performs the one or more implantation operations to form the n+ regions 152 in the substrate 132 by performing an ion implantation operation to implant ions (e.g., n-type ions) into the substrate 132 to form the n+regions 152. The ion implantation tool may direct an ion beam toward the substrate 132 such that the ions are implanted below the surface of the substrate 132 to dope the substrate 132. An implantation mask may be formed on the substrate 132, and a pattern formed in the implantation mask may be used to form the n+ regions 152 in the n-doped wells 154.

One or more well implantation operations may be performed to form p-doped wells in areas of the substrate 132 that are not enclosed by the dotted lines indicating the n-doped wells 154. The p-doped wells may be formed below the surface of the substrate 132 and adjacent to one or more n-doped wells 154. The p-doped wells may be formed such that the p-doped wells are separated or spaced apart from adjacent n-doped wells 154 by portions of the substrate 132.

As shown in FIG. 2C, the resistor 108, capacitor 110, gdPMOS transistor 112, first ggNMOS transistor 114, and second ggNMOS transistor 116 for each ESD protection circuit 102, 104, and 106 are formed over and/or on the substrate 132. The resistive structure 162 of a resistor 108 may be formed in a substrate 132 of the semiconductor device 100. In some implementations, a deposition tool may be used to deposit the resistive structure 162 using a physical vapor deposition (PVD) technique, an atomic layer deposition (ALD) technique, a chemical vapor deposition (CVD) technique, an epitaxy technique, an oxidation technique, and/or another suitable deposition technique.

The capacitor electrodes 160 and insulating layers of the capacitor 110 may be formed in a substrate 132 of the semiconductor device 100. In some implementations, a deposition tool may be used to deposit the capacitor electrodes 160 and insulating layers using a PVD technique, an ALD technique, a CVD technique, an epitaxy technique, an oxidation technique, and/or another suitable deposition technique.

In order to form the gdPMOS transistor 112, first ggNMOS transistor 114, and second ggNMOS transistor 116 for each ESD protection circuit 102, 104, and 106, dummy gate structures may be formed on the substrate 132 in positions where the gate structures 158 will be formed. More particularly, for the gdPMOS transistor 112, the dummy gate structures may be formed on portions of an n-doped well 154 between the p+ regions 150, and, for the first ggNMOS transistor 114 and the second ggNMOS transistor 116, the dummy gate structures may be formed on portions of a p-doped well between the n+ regions 152. The dummy gate structures may include a gate dielectric layer, sidewall spacers, and a sacrificial gate electrode including, for example, polycrystalline silicon (polysilicon or PO) or another material, which may be replaced with a gate electrode (e.g., metal gate electrode) in a replacement gate process.

Source/drain regions for the gdPMOS transistor 112 may be formed in the p+ regions 150, and source/drain regions for the first ggNMOS transistor 114 and second ggNMOS transistor 116 may be formed in the n+ regions 152. Using the dummy gate structures as a self-aligned implant mask, exposed regions of the substrate 132, and of the p+ regions 150 and n+ regions 152, are selectively doped to form the implant segments of the source/drain regions for the gdPMOS transistor 112, the first ggNMOS transistor 114, and the second ggNMOS transistor 116.

Following ion implantation to form the source/drain regions, an ILD layer may be formed on the substrate 132, and a replacement gate process to replace the sacrificial gate electrodes with gate electrodes may be performed, thereby forming the gate structures 158. An etch tool may be used to etch the sacrificial gate electrodes, and a deposition tool may be used to deposit the gate electrodes in place of the sacrificial gate electrodes. A planarization process such as, for example, chemical mechanical planarization (CMP) may be performed following the deposition of the gate electrodes to remove excess metal material from on top of the ILD layer.

As shown in FIGS. 2C and 2D, an interconnect layer is formed on the substrate 132. The interconnect layer includes conductive structures 146 and 148 interconnecting the components (e.g., resistor 108, capacitor 110, gdPMOS transistor 112, first ggNMOS transistor 114, and second ggNMOS transistor 116) of the ESD protection circuits 102, 104, and 106 at a first metallization level (e.g., M1) and a first via level (e.g., V1) of the interconnect layer. The interconnect layer further includes conductive structures 134, 136, 138, 140, 142, and 144 interconnecting the ESD protection circuits 102, 104, and 106 to each other, as well as to the supply voltage source 122, the first and second shared voltage sources 124 and 126, and to the ground voltage source 128. The conductive structures 134, 136, 138, 140, 142, and 144 may be at a second metallization level (e.g., M2) and a second via level (e.g., V2) of the interconnect layer.

One or more ILD layers and one or more ESLs of the interconnect layer may be formed above the substrate 132 and over the gate structures 158 of the gdPMOS transistor 112, first ggNMOS transistor 114, and second ggNMOS transistor 116 for each ESD protection circuit 102, 104, and 106. The ILD layer(s) and the ESL(s) may be deposited in an alternating manner.

A deposition tool may be used to deposit an ILD layer using a PVD technique, an ALD technique, a CVD technique, an oxidation technique, and/or another suitable deposition technique. An ILD layer may be deposited in one or more deposition operations. In some implementations, a planarization tool may be used to perform a planarization operation (e.g., a CMP operation) to planarize an ILD layer after the ILD layer is deposited.

A deposition tool may be used to deposit an ESL using a PVD technique, an ALD technique, a CVD technique, an oxidation technique, and/or another suitable deposition technique. An ESL may be deposited in one or more deposition operations. In some implementations, a planarization tool may be used to perform a planarization operation (e.g., a CMP operation) to planarize an ESL after the ESL is deposited.

Recesses may be formed through the ILD layer(s) and the ESL(s). The recesses may be formed over the source/drain regions and gate structures 158 of the gdPMOS transistor 112, first ggNMOS transistor 114, and second ggNMOS transistor 116 for each ESD protection circuit 102, 104, and 106, as well as over the capacitor electrodes 160 of the capacitor 110 and over the resistive structures 162 of the resistor 108 for each ESD protection circuit 102, 104, and 106.

In some implementations, a pattern in a photoresist layer is used to etch the ILD layer(s) and the ESL(s) to form the recesses. In these implementations, a deposition tool may be used to form the photoresist layer on the topmost ILD layer. An exposure tool may be used to expose the photoresist layer to a radiation source to pattern the photoresist layer. A developer tool may be used to develop and remove portions of the photoresist layer to expose the pattern. An etch tool may be used to etch the ILD layer(s) and the ESL(s) based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recesses based on a pattern.

Conductive structures 142 and 148 may be formed in the recesses to form, for example, source/drain contacts on the source/drain regions, gate contacts on the gate structures 158, capacitor contacts on the capacitor electrodes 160, and resistor contacts on the resistive structures 162.

A deposition tool may be used to deposit the source/drain contacts, gate contacts, capacitor contacts, and resistor contacts using a CVD technique, a PVD technique, an ALD technique, an electroplating technique, and/or another suitable deposition technique. The source/drain contacts, gate contacts, capacitor contacts, and resistor contacts may be deposited in one or more deposition operations. In some implementations, a seed layer is first deposited, and a source/drain contact, gate contact, capacitor contact, and/or resistor contact is deposited on the seed layer. In some implementations, a liner (e.g., an adhesion liner, a barrier liner) is first deposited, and a source/drain contact, gate contact, capacitor contact, and/or resistor contact is deposited on the liner. In some implementations, a planarization tool is used to perform a planarization operation (e.g., a CMP operation) to planarize the source/drain contacts, gate contacts, capacitor contacts, and resistor contacts after the source/drain contacts, gate contacts, capacitor contacts, and resistor contacts are deposited.

As indicated above, FIGS. 2A-2D are provided as examples. Other examples may differ from what is described with regard to FIGS. 2A-2D.

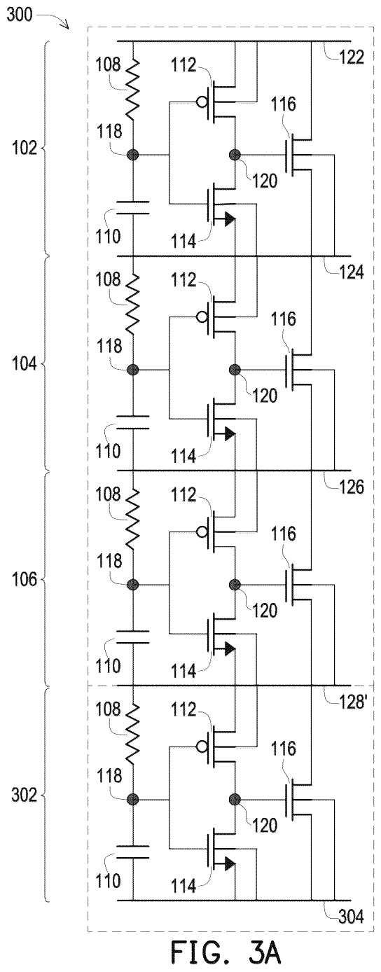

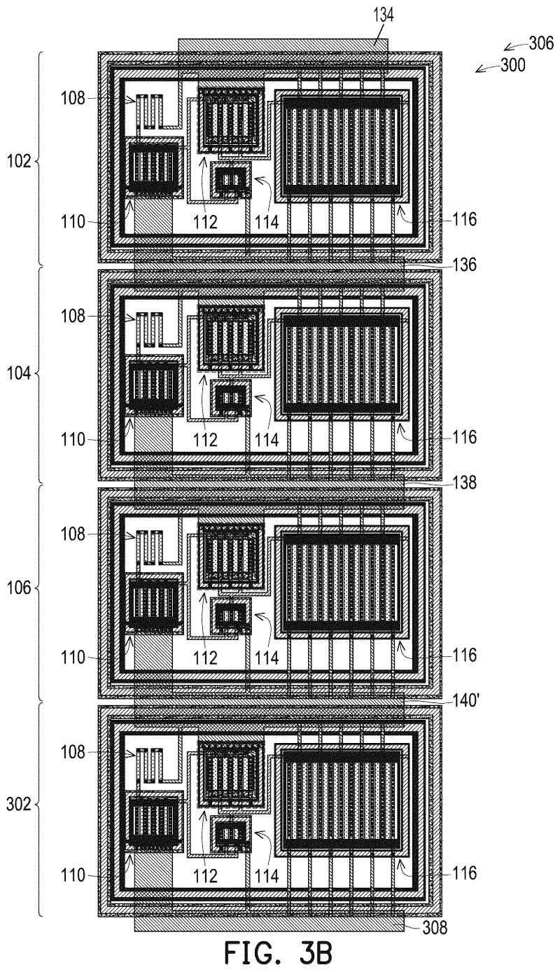

FIG. 3A is a diagram of an example semiconductor device 300 described herein. FIG. 3B is a diagram of an example implementation 306 of a layout of the semiconductor device 300 described herein. As shown in FIGS. 3A and 3B, the example semiconductor device 300 may include a similar arrangement of circuits as the example semiconductor device 100 illustrated and described in connection with FIGS. 1A-1C. For example, the example semiconductor device 300 may include components 102-126, 132-138, and 142-162. The example semiconductor device may further include an additional ESD protection circuit 302 at the end of the stacked arrangement of ESD protection circuits 102, 104, and 106. The additional ESD protection circuit 302 results in a third shared voltage source 128′ between the ESD protection circuit 106 and the additional ESD protection circuit 302, a conductive structure 140′ corresponding to the third shared voltage source 128′, and a ground voltage source 304.

Like the ESD protection circuits 102, 104, and 106, the additional ESD protection circuit 302 includes a clamp circuit with the same arrangement as the clamp circuits of the ESD protection circuits 102, 104, and 106. For example, the additional ESD protection circuit 302 includes a resistor 108, a capacitor 110, a gdPMOS transistor 112, a first ggNMOS transistor 114, a second ggNMOS transistor 116, and nodes 118 and 120.

As noted above, in a non-limiting example, each of the multiple stacked ESD protection circuits 102, 104, and 106 may be biased in a range of approximately 8 volts to approximately 10 volts instead of a single high voltage ESD circuit being biased at approximately 24 to approximately 30 volts, or at a higher voltage. The ESD protection circuits 102, 104, and 106 may include transistors with thinner gate dielectric layers and correspondingly lower threshold voltages than the gate dielectric layers and threshold voltages of the transistors of the high voltage ESD protection circuits.

In some implementations, each of the multiple stacked ESD protection circuits 102, 104, and 106 is biased at the same voltage. For example, assuming that each of the multiple stacked ESD protection circuits 102, 104, and 106 is biased at 9 volts, the total bias of the ESD protection circuits 102, 104, and 106 would be 9*3 or 27 volts. In a case where a required bias voltage is greater than 27 volts (e.g., 28 volts), an additional ESD protection circuit having a lower bias voltage than that of the ESD protection circuits 102, 104, and 106 is added to the stacked arrangement to achieve the required total bias voltage. For example, in the case of the semiconductor device 300, the additional ESD protection circuit 302 has a lower bias than that of the ESD protection circuits 102, 104, and 106. Keeping with the non-limiting operational example of a bias of 28 volts, in this case, the additional ESD protection circuit 302 may have a bias voltage of 1 volt, so that the total bias voltage for the ESD protection circuits 102, 104, 106, and 302 is (9*3)+1=28 volts. The additional ESD protection circuit 302, which may be referred to as a “low voltage ESD protection circuit” due to its lower bias voltage than that of the ESD protection circuits 102, 104, and 106, may include transistors with thinner gate dielectric layers and correspondingly lower threshold voltages than the gate dielectric layers and threshold voltages of the transistors of the ESD protection circuits 102, 104, and 106. The ESD protection circuits 102, 104, and 106 may be referred to as “middle voltage ESD protection circuits” due to their higher bias voltage than the bias voltage of the low voltage ESD protection circuit, and lower bias voltage than the bias voltage of a high voltage ESD protection circuit.

In some implementations, the thickness of the gate dielectric layers for the transistors of the middle voltage ESD protection circuits is included in the range of approximately 10 nanometers to approximately 25 nanometers. If the thickness of the gate dielectric layers is less than approximately 10 nanometers, the gate dielectric layers of the transistors of the middle voltage ESD protection circuits may break down. If the thickness of the gate dielectric layers is greater than approximately 25 nanometers, driving of the transistors of the middle voltage ESD protection circuits may be too weak and lead to weak turn on capability of the transistors of the middle voltage ESD protection circuits during an ESD event. However, other values for the range are within the scope of the present disclosure.

In some implementations, the thickness of the gate dielectric layers for the transistors of the low voltage ESD protection circuits is included in the range of approximately 0.3 nanometers to approximately 7 nanometers. If the thickness of the gate dielectric layers is less than approximately 0.3 nanometers, the gate dielectric layers of the transistors of the low voltage ESD protection circuits may break down. If the thickness of the gate dielectric layers is greater than approximately 7 nanometers, driving of the transistors of the low voltage ESD protection circuits may be too weak and lead to weak turn on capability of the transistors of the middle voltage ESD protection circuits during an ESD event. However, other values for the range are within the scope of the present disclosure.

The operation of the ESD protection circuits 102, 104, and 106 in the semiconductor device 300 proceeds in a similar manner to that of the ESD protection circuits 102, 104, and 106 in the semiconductor device 100, except that following the activation of the second ggNMOS transistor 116 of the ESD protection circuit 106, instead of being transmitted to the ground voltage source, further dissipated voltage corresponding to a portion of the original voltage inputted to the supply voltage source 122 is transmitted from the source/drain region of the second ggNMOS transistor 116 of the ESD protection circuit 106 to the third shared voltage source 128′, which activates the additional ESD protection circuit 302 in a similar manner to the ESD protection circuits 102, 104, and 106. In more detail, the dissipated voltage applied to the third shared voltage source 128′ causes the capacitor 110 of the additional ESD protection circuit 302 to be shorted. As a result, the gdPMOS transistor 112 of the additional ESD protection circuit 302 is turned on, while the first ggNMOS transistor 114 of the additional ESD protection circuit 302 is off. The gdPMOS transistor 112 of the additional ESD protection circuit 302 is turned on because the Vgs resulting from the dissipated voltage inputted to the third shared voltage source 128′ is greater than the Vt of the gdPMOS transistor 112 of the additional ESD protection circuit 302. The activation of the gdPMOS transistor 112 of the additional ESD protection circuit 302 causes the gate of the second ggNMOS transistor 116 of the additional ESD protection circuit 302 to receive a voltage approximately equal to the dissipated voltage. As a result, the second ggNMOS transistor 116 of the additional ESD protection circuit 302 is turned on because the Vgs is greater than the Vt of the second ggNMOS transistor 116 of the additional ESD protection circuit 302. Due to the activation of the second ggNMOS transistor 116 of the additional ESD protection circuit 302, a final dissipated voltage corresponding to a portion of the original voltage inputted to the supply voltage source 122 is transmitted from the source/drain region of the second ggNMOS transistor 116 of the additional ESD protection circuit 302 to the ground voltage source 304.

As shown in FIG. 3B, in the example implementation 306, the layout of the ESD protection circuits 102, 104, and 106 in the semiconductor device 300 is the same as the layout of the ESD protection circuits 102, 104, and 106 in the semiconductor device 100. However, due to the additional ESD protection circuit 302, a conductive structure 140′ at the bottom side of the ESD protection circuit 106 corresponds to the third shared voltage source 128′ instead of a ground voltage source. The conductive structure 140′ is similar to the conductive structures 136 and 138, which respectively correspond to the first and second shared voltage sources 124 and 126.

The additional ESD circuit 302 has the same layout as that of the ESD protection circuits 102, 104, and 106, except that in the additional ESD protection circuit 302, the resistor 108, the gdPMOS transistor 112, and the second ggNMOS transistor 116 are connected to the third shared voltage source 128′ through the conductive structure 140′. For example, a source/drain region and a gate of the gdPMOS transistor 112, and source/drain region of the second ggNMOS transistor 116 are electrically coupled to the third shared voltage source 128′ through the conductive structure 140′. Also, in the additional ESD protection circuit 302, the capacitor 110, the first ggNMOS transistor 114, and the second ggNMOS transistor 116 are connected to the ground voltage source 304 through the conductive structure 308. For example, a source/drain region and a gate of the first ggNMOS transistor 114, and a source/drain region and a gate of the second ggNMOS transistor 116 are electrically coupled to the ground voltage source 304 through the conductive structure 308.

As indicated above, FIGS. 3A and 3B are provided as examples. Other examples may differ from what is described with regard to FIGS. 3A and 3B.

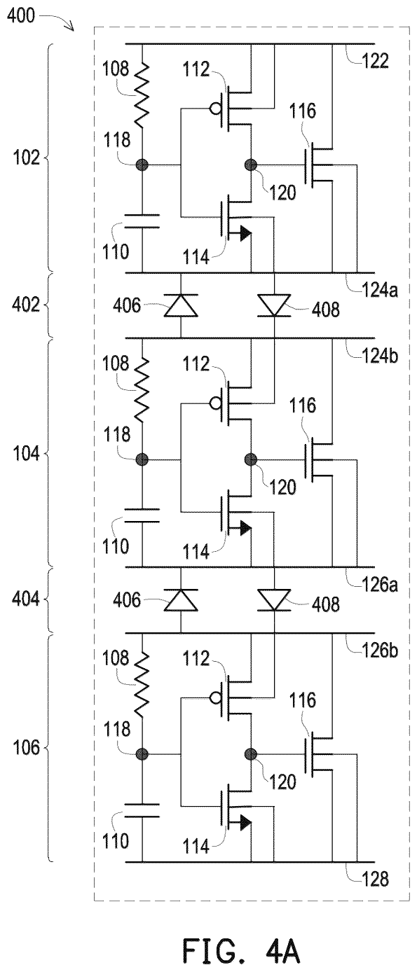

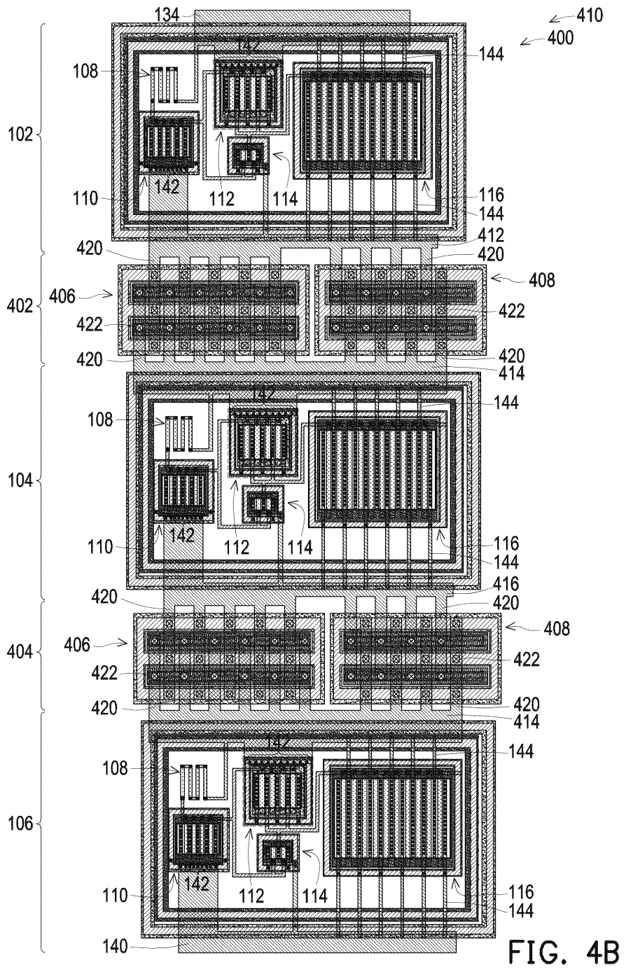

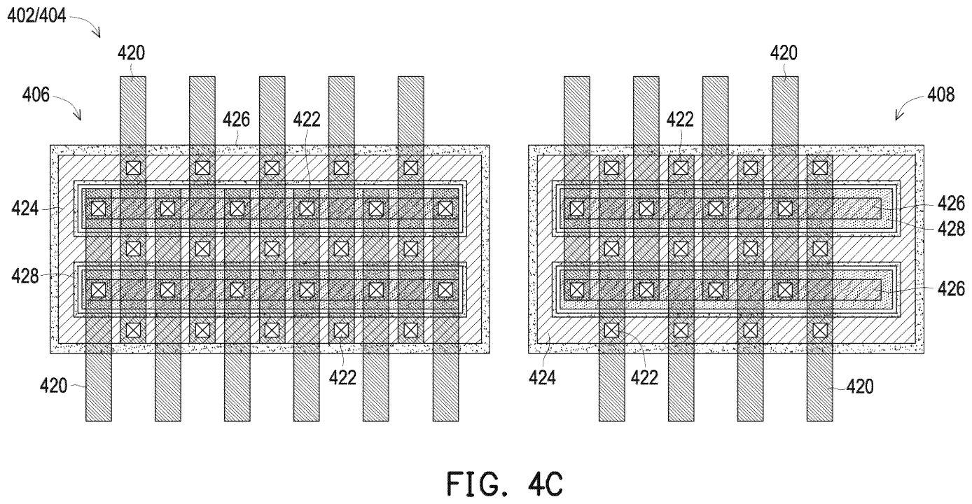

FIG. 4A is a diagram of an example semiconductor device 400 described herein. FIG. 4B is a diagram of an example implementation 410 of a layout of the semiconductor device 400 described herein. As shown in FIGS. 4A and 4B, the example semiconductor device 400 may include a similar arrangement of circuits as the example semiconductor device 100 illustrated and described in connection with FIGS. 1A-1C. For example, the example semiconductor device 400 may include components 102-122, 128, 132, 134, and 140-162. The example semiconductor device may further include back-to-back (B2B) diode structures 402 and 404 in the stacked arrangement between ESD protection circuits 102 and 104, and between ESD protection circuits 104 and 106. The B2B diode structures 402 and 404 each include a first diode 406 and a second diode 408. Each first diode 406 conducts current in a first direction, and each second diode 408 conducts current in a second direction opposite the first direction. For example, the first diode 406 in the B2B diode structure 402 conducts current from the ESD protection circuit 104 to the ESD protection circuit 102, and the second diode 408 in the B2B diode structure 402 conducts current from the ESD protection circuit 102 to the ESD protection circuit 104. Similarly, in the B2B diode structure 404, the first diode 406 conducts current from the ESD protection circuit 106 to the ESD protection circuit 104, and the second diode 408 conducts current from the ESD protection circuit 104 to the ESD protection circuit 106.

In the semiconductor device 400, the first and second diodes 406 and 408 of the B2B diode structure 402 are connected between a first mid-level voltage source 124a and a second mid-level voltage source 124b, and the first and second diodes 406 and 408 of the B2B diode structure 404 are connected between a third mid-level voltage source 126a and a fourth mid-level voltage source 126b. In more detail, in the B2B diode structure 402, the cathode and the anode of the first diode 406 are respectively connected to the first mid-level voltage source 124a and to the second mid-level voltage source 124b, and the cathode and the anode of the second diode 408 are respectively connected to the second mid-level voltage source 124b and to the first mid-level voltage source 124a. In the B2B diode structure 404, the cathode and the anode of the first diode 406 are respectively connected to the third mid-level voltage source 126a and to the fourth mid-level voltage source 126b, and the cathode and the anode of the second diode 408 are respectively connected to the fourth mid-level voltage source 126b and to the third mid-level voltage source 126a. Each of the B2B diode structures 402 and 404 permits current to flow in a particular direction when the applied voltage to a first diode 406 or a second diode 408 exceeds a diode's breakdown voltage.

The ESD protection circuit 102 is connected between the supply voltage source 122 and the first mid-level voltage source 124a. In the ESD protection circuit 102, the gate and a source/drain region of the first ggNMOS transistor 114 are connected to the first mid-level voltage source 124a. The gate and a source/drain region of the second ggNMOS transistor 116 are connected to the first mid-level voltage source 124a. The resistor 108 is connected to the supply voltage source 122, and the capacitor 110, which is connected in series with resistor 108, is further connected to the first mid-level voltage source 124a.

The ESD protection circuit 104 is connected between the second mid-level voltage source 124b and the third mid-level voltage source 126a. In the ESD protection circuit 104, the gate and a source/drain region of the gdPMOS transistor 112 are connected to the second mid-level voltage source 124b. The gate and a source/drain region of the first ggNMOS transistor 114 are connected to the third mid-level voltage source 126a. The gate and a source/drain region of the second ggNMOS transistor 116 are connected to the third mid-level voltage source 126a. The resistor 108 is connected to the second mid-level voltage source 124b, and the capacitor 110, which is connected in series with resistor 108, is further connected to the third mid-level voltage source 126a.

The ESD protection circuit 106 is connected between the fourth mid-level voltage source 126b and the ground voltage source 128. In the ESD protection circuit 106, the gate and a source/drain region of the gdPMOS transistor 112 are connected to the fourth mid-level voltage source 126b. The gate and a source/drain region of the first ggNMOS transistor 114 are connected to the ground voltage source 128. The gate and a source/drain region of the second ggNMOS transistor 116 are connected to the ground voltage source 128. The resistor 108 is connected to the second shared voltage source 126, and the capacitor 110, which is connected in series with resistor 108, is further connected to the ground voltage source 128.

A source/drain region of the first ggNMOS transistor 114 of the ESD protection circuit 102 is electrically coupled to a source/drain region of the first ggNMOS transistor 114 of the ESD protection circuit 104 through the first mid-level voltage source 124a, through the B2B diode structure 402 (e.g., through the first diode 406 and/or the second diode 408), and through the second mid-level voltage source 124b. A source/drain region of the second ggNMOS transistor 116 of the ESD protection circuit 102 is electrically coupled to a source/drain region of the second ggNMOS transistor 116 of the ESD protection circuit 104 through the first and second mid-level voltage sources 124a and 124b, and through the B2B diode structure 402 (e.g., through the first diode 406 and/or the second diode 408).

A source/drain region of the first ggNMOS transistor 114 of the ESD protection circuit 104 is electrically coupled to a source/drain region of the first ggNMOS transistor 114 of the ESD protection circuit 106 through the third and fourth mid-level voltage sources 126a and 126b, and through the B2B diode structure 404 (e.g., through the first diode 406 and/or the second diode 408). A source/drain region of the second ggNMOS transistor 116 of the ESD protection circuit 104 is electrically coupled to a source/drain region of the second ggNMOS transistor 116 of the ESD protection circuit 106 through the third and fourth mid-level voltage sources 126a and 126b, and through the B2B diode structure 404 (e.g., through the first diode 406 and/or the second diode 408).

The operation of the ESD protection circuits 102, 104, and 106 in the semiconductor device 400 proceeds in a similar manner to that of the ESD protection circuits 102, 104, and 106 in the semiconductor device 100, except that following the activation of the second ggNMOS transistor 116 of the ESD protection circuit 102, dissipated voltage corresponding to the voltage inputted to the supply voltage source 122 is transmitted from the source/drain region of the second ggNMOS transistor 116 of the ESD protection circuit 102 to the first mid-level voltage source 124a, through the second diode 408 of the B2B diode structure 402, and to the second mid-level voltage source 124b, which activates the ESD protection circuit 104 in a similar manner to the ESD protection circuit 102. In more detail, the dissipated voltage applied to the second mid-level voltage source 124b causes the capacitor 110 of the ESD protection circuit 104 to be shorted. As a result, the gdPMOS transistor 112 of the ESD protection circuit 104 is turned on, while the first ggNMOS transistor 114 of the ESD protection circuit 104 is off. The gdPMOS transistor 112 of the ESD protection circuit 104 is turned on because the Vgs resulting from the dissipated voltage inputted to the second mid-level voltage source 124b is greater than the Vt of the gdPMOS transistor 112 of the ESD protection circuit 104. The activation of the gdPMOS transistor 112 of the ESD protection circuit 104 causes the gate of the second ggNMOS transistor 116 of the ESD protection circuit 104 to receive a voltage approximately equal to the dissipated voltage. As a result, the second ggNMOS transistor 116 of the ESD protection circuit 104 is turned on because the Vgs is greater than the Vt of the second ggNMOS transistor 116 of the ESD protection circuit 104.

Due to the activation of the second ggNMOS transistor 116 of the ESD protection circuit 104, further dissipated voltage corresponding to a portion of the original voltage inputted to the supply voltage source 122 is transmitted from the source/drain region of the second ggNMOS transistor 116 of the ESD protection circuit 104 to the third mid-level voltage source 126a, through the second diode 408 of the B2B diode structure 404, and to the fourth mid-level voltage source 126b, which activates the ESD protection circuit 106 in a similar manner to the ESD protection circuits 102 and 104. In more detail, the dissipated voltage applied to the fourth mid-level voltage source 126b causes the capacitor 110 of the ESD protection circuit 106 to be shorted. As a result, the gdPMOS transistor 112 of the ESD protection circuit 106 is turned on, while the first ggNMOS transistor 114 of the ESD protection circuit 106 is off. The gdPMOS transistor 112 of the ESD protection circuit 106 is turned on because the Vgs resulting from the dissipated voltage inputted to the fourth mid-level voltage source 126b is greater than the Vt of the gdPMOS transistor 112 of the ESD protection circuit 106. The activation of the gdPMOS transistor 112 of the ESD protection circuit 106 causes the gate of the second ggNMOS transistor 116 of the ESD protection circuit 106 to receive a voltage approximately equal to the dissipated voltage. As a result, the second ggNMOS transistor 116 of the ESD protection circuit 106 is turned on because the Vgs is greater than the Vt of the second ggNMOS transistor 116 of the ESD protection circuit 106. Due to the activation of the second ggNMOS transistor 116 of the ESD protection circuit 106, a final dissipated voltage corresponding to a portion of the original voltage inputted to the supply voltage source 122 is transmitted from the source/drain region of the second ggNMOS transistor 116 of the ESD protection circuit 106 to the ground voltage source 128.

As noted herein, in some implementations, each of the multiple stacked ESD protection circuits 102, 104, and 106 is biased at the same voltage. For example, assuming that each of the multiple stacked ESD protection circuits 102, 104, and 106 is biased at 9 volts, the total bias of the ESD protection circuits 102, 104, and 106 would be 9*3 or 27 volts. In a case where a required bias voltage is greater than 27 volts (e.g., 28 volts), the B2B diode structures 402 and 402, each having a lower bias voltage than that of the ESD protection circuits 102, 104, and 106, are added to the stacked arrangement to achieve the required total bias voltage. For example, in the case of the semiconductor device 400, the B2B diode structures 402 and 402 may each have a bias voltage of 0.5 volts, so that the total bias voltage for the ESD protection circuits 102, 104, 106, and the B2B diode structures 402 and 404 is (9*3)+(2*0.5)=28 volts.

As shown in FIG. 4B, in the example implementation 410, the layout of the ESD protection circuits 102, 104, and 106 in the semiconductor device 400 is the same as the layout of the ESD protection circuits 102, 104, and 106. However, due to the addition of the B2B diode structures 402 and 404, a conductive structure 412 at the bottom side of the ESD protection circuit 102 corresponds to the first mid-level voltage source 124a, the conductive structure 414 at the top side of the ESD protection circuit 104 corresponds to the second mid-level voltage source 124b, the conductive structure 416 at the bottom side of the ESD protection circuit 104 corresponds to the third mid-level voltage source 126a, and the conductive structure 418 at the top side of the ESD protection circuit 106 corresponds to the fourth mid-level voltage source 126b. The conductive structure 140 corresponds to the ground voltage source 128. The conductive structures 412-418 are similar to the conductive structures 134, 136 and 140′.

The first and second diodes 406 and 408 of the B2B diode structure 402 are electrically coupled to the conductive structures 412 and 414 through conductive structures 420 and 422, and the first and second diodes 406 and 408 of the B2B diode structure 404 are electrically coupled to the conductive structures 416 and 418 through conductive structures 420 and 422. The conductive structures 412-420 may be metallization level type conductive structures (e.g., trenches, conductive lines), and the conductive structures 422 may be interconnect type conductive structures (e.g., vias).

FIG. 4C illustrates an enlarged view of the layout of the B2B diode structures 402 and 404. As shown in FIG. 4C, each of the first and second diodes 406 and 408 includes an active area defining region 424, p+ regions 426, and n+ regions 428. Similar to the active area defining regions 156, the active area defining region 424 defines an area in which active regions of different components of the first and second diodes 406 and 408 (e.g., anodes, cathodes, pn junctions) are included. The p+ regions 426 (e.g., p-type regions) may be regions of a substrate that are doped with one or more p-type dopants, such as boron (B), gallium (Ga), and/or indium (In), among other examples. The n+ regions 428 (e.g., n-type regions) may be regions of a substrate that are doped with one or more n-type dopants, such as phosphorous (P), arsenic (As), bismuth (Bi), and/or antimony (Sb), among other examples.

As indicated above, FIGS. 4A-4C are provided as examples. Other examples may differ from what is described with regard to FIGS. 4A-4C.

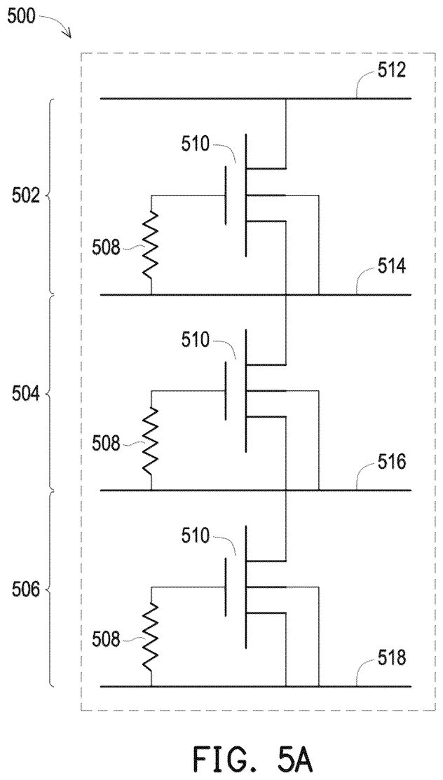

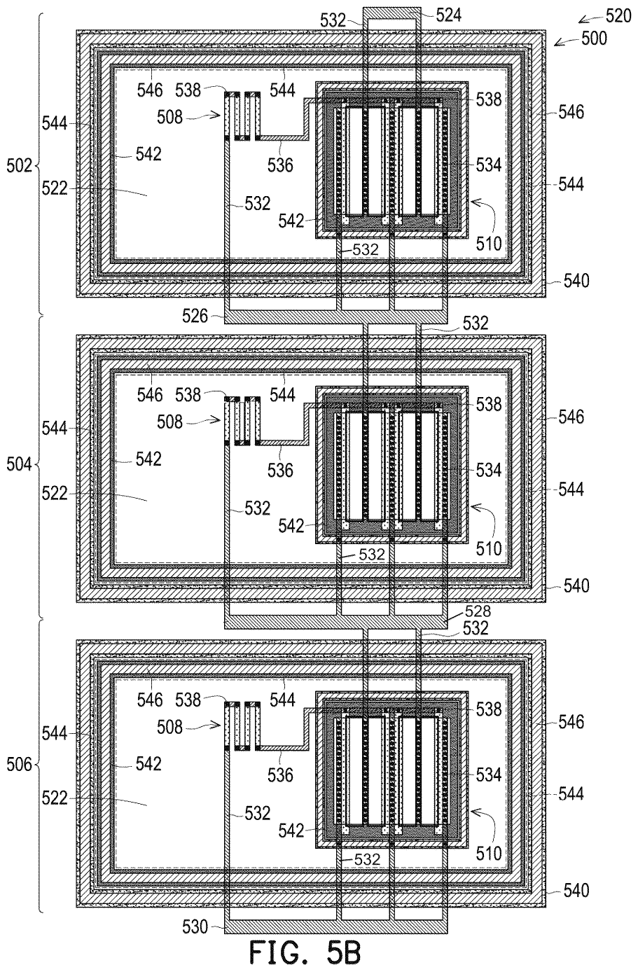

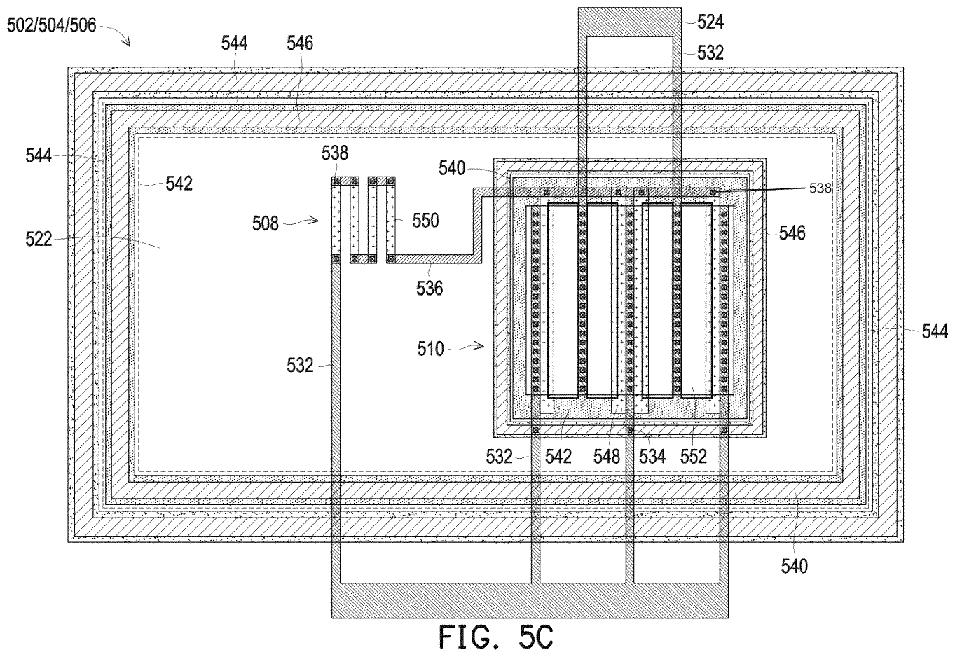

FIG. 5A is a diagram of an example semiconductor device 500 described herein. The semiconductor device 500 may include a logic device (e.g., a processor, CPU, a GPU), a memory device (e.g., a DRAM device, an SRAM device), a display panel device (e.g., a display panel driver including a driver IC, a line driver IC, a level shifter IC), and/or another type of semiconductor device 500 that includes high voltage semiconductor devices.

An example semiconductor device 500 may include a device circuit, and a plurality of ESD protection circuits 502, 504, and 506, among other types of circuits. In some implementations, the device circuit includes a high voltage device circuit, and high voltage transistors. A high voltage transistor may include a high voltage planar transistor, a high voltage finFET, a high voltage nanostructure (e.g., a GAA transistor, a nanowire transistor, a nanosheet transistor, a multi-bridge channel transistor, a nanoribbon transistor), and/or another type of high voltage transistor that is configured to operate at high voltages (e.g., greater than 40 volts, for example).

The ESD protection circuits 502, 504, and 506 may each include a grounded-gate metal-oxide semiconductor circuit (e.g., a ggNMOS circuit) that is configured to provide ESD protection for the device circuit against high voltage spikes, high voltage surges, and/or other types of high voltage events.

In the example semiconductor device 500, each ESD protection circuit 502, 504, and 506 is a ggNMOS circuit including a resistor 508 and a ggNMOS transistor 510. Similar to the second ggNMOS transistor 116 of the ESD protection circuits 102, 104, and 106, the ggNMOS transistor 510 may be a large width FET having an active region with a width the same as or substantially the same as the width WD1 of the second ggNMOS transistor 116.

The resistor 108 is connected to the gate of the ggNMOS transistor 510. The ESD protection circuit 502 is connected to a supply voltage source 512, providing a positive supply voltage (e.g., drain voltage (VDD)) to the ESD protection circuit 502. The ESD protection circuit 502 and the ESD protection circuit 504 are connected to a first shared voltage source 514, where an output voltage of the ESD protection circuit 502 is provided to the ESD protection circuit 504 as a supply voltage. The ESD protection circuit 504 and the ESD protection circuit 506 are connected to a second shared voltage source 516, where an output voltage of the ESD protection circuit 504 is provided to the ESD protection circuit 506 as a supply voltage. The ESD protection circuit 506 is connected to a ground (e.g., negative supply voltage) voltage source 518.

The ESD protection circuits 502, 504, and 506 are interconnected in a stacked arrangement, where the ESD protection circuits 502, 504, and 506 are connected to each other and connected between the supply voltage source 512 and the ground voltage source 518. In more detail, a first source/drain region of the ggNMOS transistor 510 of the ESD protection circuit 502 is connected to the supply voltage source 512, and a gate and a source/drain region of the ggNMOS transistor 510 are connected to the first shared voltage source 514. The resistor 108 of the ESD protection circuit 502 is connected to a gate of the ggNMOS transistor 510, and to the first shared voltage source 514.

A first source/drain region of the ggNMOS transistor 510 of the ESD protection circuit 504 is connected to the first shared voltage source 514, and a gate and a source/drain region of the ggNMOS transistor 510 are connected to the second shared voltage source 516. The resistor 108 of the ESD protection circuit 504 is connected to a gate of the ggNMOS transistor 510, and to the second shared voltage source 514. A source/drain region of the ggNMOS transistor 510 of the ESD protection circuit 502 is electrically coupled to a source/drain region of the ggNMOS transistor 510 of the ESD protection circuit 504 through the first shared voltage source 514.

A first source/drain region of the ggNMOS transistor 510 of the ESD protection circuit 506 is connected to the second shared voltage source 516, and a gate and a source/drain region of the ggNMOS transistor 510 are connected to the ground voltage source 518. The resistor 108 of the ESD protection circuit 506 is connected to a gate of the ggNMOS transistor 510, and to the ground voltage source 518. A source/drain region of the ggNMOS transistor 510 of the ESD protection circuit 504 is electrically coupled to a source/drain region of the ggNMOS transistor 510 of the ESD protection circuit 506 through the second shared voltage source 516.

For each of the ESD protection circuits 502, 504, and 506, there is a parasitic capacitance between the gate of the ggNMOS transistor 510 and the first source/drain region of the ggNMOS transistor 510. In operation, when an input voltage satisfying a threshold to qualify for an ESD event (e.g., a voltage satisfying a BV) is applied to the supply voltage source 512, the parasitic capacitance is shorted. As a result, the ggNMOS transistor 510 of the ESD protection circuit 502 is turned on. The ggNMOS transistor 510 of the ESD protection circuit 502 is turned on because the gate-to-source voltage (Vgs) resulting from the input voltage to the supply voltage source 512 is greater than the threshold voltage (Vt) of the ggNMOS transistor 510 of the ESD protection circuit 502.

Due to the activation of the ggNMOS transistor 510 of the ESD protection circuit 502, dissipated voltage corresponding to the voltage inputted to the supply voltage source 512 is transmitted from the source/drain region of the ggNMOS transistor 510 of the ESD protection circuit 502 to the first shared voltage source 514, which activates the ESD protection circuit 504 in a similar manner to the ESD protection circuit 502. In more detail, the dissipated voltage applied to the first shared voltage source 514 causes the parasitic capacitance of the ESD protection circuit 504 to be shorted. As a result, the ggNMOS transistor 510 of the ESD protection circuit 504 is turned on. The ggNMOS transistor 510 of the ESD protection circuit 504 is turned on because the Vgs resulting from the dissipated voltage inputted to the first shared voltage source 514 is greater than the Vt of the ggNMOS transistor 510 of the ESD protection circuit 504.

Due to the activation of the ggNMOS transistor 510 of the ESD protection circuit 504, further dissipated voltage corresponding to a portion of the original voltage inputted to the supply voltage source 512 is transmitted from the source/drain region of the ggNMOS transistor 510 of the ESD protection circuit 504 to the second shared voltage source 516, which activates the ESD protection circuit 506 in a similar manner to the ESD protection circuits 502 and 504. In more detail, the dissipated voltage applied to the second shared voltage source 516 causes the parasitic capacitance of the ESD protection circuit 506 to be shorted. As a result, the ggNMOS transistor 510 of the ESD protection circuit 506 is turned on. The ggNMOS transistor 510 of the ESD protection circuit 506 is turned on because the Vgs resulting from the dissipated voltage inputted to the second shared voltage source 516 is greater than the Vt of the ggNMOS transistor 510 of the ESD protection circuit 506. Due to the activation of the ggNMOS transistor 510 of the ESD protection circuit 506, a final dissipated voltage corresponding to a portion of the original voltage inputted to the supply voltage source 512 is transmitted from the source/drain region of the ggNMOS transistor 510 of the ESD protection circuit 506 to the ground voltage source 518.

Similar to the ESD protection circuits 102, 104, and 106, the multiple stacked ESD protection circuits 502, 504, and 506 may each be biased at a lower voltage than a single high voltage ESD protection circuit. In a non-limiting example, each of the multiple stacked ESD protection circuits 502, 504, and 506 may be biased in a range of approximately 8 volts to approximately 10 volts, instead of a single high voltage ESD circuit being biased at approximately 24 to approximately 30 volts, or at a higher voltage. As a result of the lower bias voltage for each circuit, the ESD protection circuits 502, 504, and 506 may include transistors with thinner gate dielectric layers and correspondingly lower threshold voltages than the gate dielectric layers and threshold voltages of the transistors of the high voltage ESD protection circuits. Due to their thinner gate dielectric layers and correspondingly lower threshold voltages, the transistors in the ESD protection circuits 502, 504, and 506, including the ggNMOS transistors 510 with large active region width values, may fully turn on in response to short (e.g., ~1 nanosecond) CDM pulses. Combined bias voltages of multiple interconnected ESD protection circuits 502, 504, and 506 in a stacked arrangement permits use of the stacked arrangement for high voltage applications. For example, the total of the bias voltages of multiple ESD protection circuits (e.g., ESD protection circuits 502, 504, and 506) may be equal to the bias voltage of a single high voltage ESD protection circuit, so that the multiple interconnected ESD protection circuits may be used in place of a single high voltage ESD protection circuit to fully dissipate CDM current, leading to improved performance and adequate responses to ESD events. As explained in more detail herein, the number of ESD protection circuits can vary based on individual bias voltage values of each ESD protection circuit, and a required total bias voltage. In some implementations, the bias voltages of each of the ESD protection circuits in a stacked arrangement are equal, or substantially equal, to each other.

Depending upon a required total bias value of the plurality of ESD protection circuits (e.g., ESD protection circuits 502, 504, and 506), the number of ESD protection circuits in a stacked arrangement may vary. For example, in some implementations, the number of ESD protection circuits in a stacked arrangement may vary from 3 to 6.

FIG. 5B is a diagram of an example implementation 520 of a layout of the semiconductor device 500 described herein. FIG. 5C illustrates an enlarged view of the layout of an ESD protection circuit 502, 504, or 506. As shown in FIG. 5B, each ESD protection circuit 502, 504, and 506 is on a substrate 522, which may be substantially the same as the substrate 132. The resistor 508 and the ggNMOS transistor 510 of each ESD protection circuit 502, 504, and 506 may be formed on a substrate 522.

The semiconductor device 500 may include an interconnect layer including a plurality of conductive structures 524, 526, 528, 530, 532, 534, 536, and 538 (e.g., electrically conductive structures) formed in one or more dielectric layers on a substrate 522. The dielectric layers may include backend dielectric layers (e.g., ILD layers, IMD layers and ESLs) that are arranged in a direction that is approximately orthogonal to the substrate 522. The dielectric layers may each include various dielectric materials, such as an oxide (e.g., a silicon oxide (SiOₓ) and/or another oxide material), a USG, a BSG, an FSG, an ELK dielectric material having a dielectric constant that is less than approximately 2.5, a silicon nitride (SiₓN_{y}), silicon carbide (SiC), silicon oxynitride (SiON), and/or another suitable dielectric material.

The conductive structures 524, 526, 528, 530, 532, 534, 536, and/or 538 are electrically coupled and/or physically coupled to the resistor 108 and/or the ggNMOS transistor 510 of each ESD protection circuit 502, 504, and 506, and/or other structures of the semiconductor device 500. Moreover, the conductive structures 524, 526, 528, 530, 532, 534, 536 and/or 538 may be electrically interconnected together in the interconnect layer. The conductive structures 524, 526, 528, 530, 532, 534, 536, and/or 538 correspond to circuit routing that enables signals and/or power to be provided to and/or from components of the ESD protection circuits 502, 504, and 506. The conductive structures 524, 526, 528, 530, 532, 534, 536, and/or 538 may include a combination of conductive structures that extend primarily horizontally in the interconnect layer (e.g., trenches, conductive lines) and that are interconnected by interconnect structures (e.g., vias) that extend primarily vertically in the interconnect layer. The conductive structures 524, 526, 528, 530, 532, 534, 536, and/or 538 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

The conductive interconnects of the interconnect layer may be arranged in a vertical manner to facilitate electrical signals and/or power to be routed between integrated circuit devices in different layers. The conductive structures 524, 526, 528, 530, 532, 534, 536, and/or 538 may be arranged in alternating layers of metallization layers (referred to as “M” layers) and via layers (referred to as “V” layers). Each metallization layer may include one or more conductive structures laterally arranged in the interconnect layer, and each via layer may include one or more interconnect structures that interconnect the metallization layers in the interconnect layer. As an example, a metal-0 (M0) layer may be located at the bottom of the interconnect layer, a via-0 (V0) layer may be located above and coupled to the M0 layer in the interconnect layer, a metal-1 (M1) layer may be located above and coupled to the V0 layer in the interconnect layer, a via-1 (V1) layer may be located above and coupled to the M1 layer in the interconnect layer, a metal-2 (M2) layer may be located above and electrically coupled to the V1 layer in the interconnect layer, and so on.

For example, the conductive structures 524, 526, 528, and 530 may be part of one or more metallization layers and may respectively correspond to the supply voltage source 512, the first shared voltage source 514, the second shared voltage source 516, and the ground voltage source 518. The conductive structures 532 may be metallization layer structures connecting the resistor 108 and/or the ggNMOS transistor 510 of each ESD protection circuit 502, 504, and/or 506 to the conductive structures 524, 526, 528, and/or 530. The conductive structures 534 may be interconnect structures (e.g., vias) connecting the resistor 108 and/or the ggNMOS transistor 510 of each ESD protection circuit 502, 504, and/or 506 to the conductive structures 532.

In more detail, in the ESD protection circuit 502, a first source/drain region of the ggNMOS transistor 510 is connected to the conductive structure 524 through conductive structures 532 and 534. The gate and a second source/drain region of the ggNMOS transistor 510 are connected to the conductive structure 526 through conductive structures 532 and 534. The resistor 108 is connected to the conductive structure 526 through conductive structures 532 and 534.

In the ESD protection circuit 504, a first source/drain region of the ggNMOS transistor 510 is connected to the conductive structure 526 through conductive structures 532 and 534. The gate and a second source/drain region of the ggNMOS transistor 510 are connected to the conductive structure 528 through conductive structures 532 and 534. The resistor 108 is connected to the conductive structure 528 through conductive structures 532 and 534.

In the ESD protection circuit 506, a first source/drain region of the ggNMOS transistor 510 is connected to the conductive structure 528 through conductive structures 532 and 534. The gate and a second source/drain region of the ggNMOS transistor 510 are connected to the conductive structure 530 through conductive structures 532 and 534. The resistor 108 is connected to the conductive structure 530 through conductive structures 532 and 534.

A source/drain region of the ggNMOS transistor 510 of the ESD protection circuit 502 is electrically coupled to a source/drain region of the ggNMOS transistor 510 of the ESD protection circuit 504 through the conductive structures 526, 532 and 534. A source/drain region of the ggNMOS transistor 510 of the ESD protection circuit 504 is electrically coupled to a source/drain region of the ggNMOS transistor 510 of the ESD protection circuit 506 through the conductive structures 528, 532 and 534.

The conductive structures 536 may be metallization layer structures connecting the resistor 108 and the ggNMOS transistor 510 of each ESD protection circuit 502, 504, and/or 506 to each other. The conductive structures 538 may be interconnect structures (e.g., vias) extending between the conductive structures 536 and portions of the resistor 108 and/or the ggNMOS transistor 510 of each ESD protection circuit 502, 504, and/or 506. For example, for an ESD protection circuit 502, 504 or 506, a resistor 108 may be electrically coupled to the gate of the ggNMOS transistor 510 through the conductive structures 536 and 538.

FIGS. 5B and 5C further illustrate a plurality of doped regions that are included in the substrates 522. For example, the ESD protection circuits 502, 504, and 506 may include a plurality of p+ regions 540, n+ regions 542, n-doped wells 544 and p-doped wells (not labeled) in remaining portions of the substrates 522 (areas that are not enclosed by the dotted lines indicating the n-doped wells 544 are p-doped wells). The p-doped wells may be regions of a substrate 522 that are doped with one or more p-type dopants, such as boron (B), gallium (Ga), and/or indium (In), among other examples. The n-doped wells 544 may be regions of a substrate 522 that are doped with one or more n-type dopants, such as phosphorous (P), arsenic (As), bismuth (Bi), and/or antimony (Sb), among other examples. Including the p-doped wells may reduce on resistance (Rₒₙ) for the ESD protection circuits 502, 504, and 506. Including the n-doped wells 544 may reduce on resistance (Rₒₙ) for the ESD protection circuits 502, 504, and 506.

The p+ regions 540 (e.g., p-type regions) may be regions of the substrate 522 that are doped with one or more p-type dopants, such as boron (B), gallium (Ga), and/or indium (In), among other examples. The n+ regions 542 (e.g., n-type regions) may be regions of the substrate 522 that are doped with one or more n-type dopants, such as phosphorous (P), arsenic (As), bismuth (Bi), and/or antimony (Sb), among other examples.

The p-doped wells and the p+ regions 540 may have different dopant concentrations. For example, the dopant concentration in the p+ regions 540 may be greater relative to a dopant concentration in the p-doped wells.

The n-doped wells 544 and the n+ regions 542 may have different dopant concentrations. For example, the dopant concentration in the n+ regions 542 may be greater than a dopant concentration in the n-doped wells 544.

FIGS. 5B and 5C further illustrate active area defining regions 546, in which active regions of different components (e.g., transistors) are defined. For example, active regions of a device such as a transistor include parts of a substrate encompassing the source/drain regions and the area between the source/drain regions. Source/drain regions of the ggNMOS transistor 510 are within the active area defining regions 546. The conductive structures 532 (e.g., metallization structures) extend into the active regions to connect to the source/drain regions through the conductive structures 534 (e.g., interconnect structures). Gate structures 548 are further illustrated in the ggNMOS transistor 510. A gate structure 548 may include a gate dielectric layer on the substrate 522. The gate dielectric layer may be included between the substrate 522 and a gate electrode.

The resistor 508 of the ESD protection circuits 502, 504, and 506 may include a resistive structure 550. The resistive structure 550 may include thick film materials, thin film materials, and/or metal-oxide materials. The resistor 108 may be connected to the gate structures 548 of the ggNMOS transistor 510 through conductive structures 538 (e.g., interconnect structures) connected to the resistive structure 550 and conductive structures 536 (e.g., metallization level structures) between the resistor 108 and the gate structures 548 of the ggNMOS transistor 510.

In some implementations, a resist protective oxide (RPO) layer 552 is formed in an active region of the ggNMOS transistor 510 over source/drain regions and over sides of gate structures 548 facing the source/drain regions. The RPO layer 552 may include an oxide material such as a silicon oxide (SiOₓ such as SiO₂) and/or another dielectric oxide material. The RPO layer 552 may be included in an ESD protection circuit 502, 504, and/or 506 for reduced surface field (RESURF) tuning. The RPO layer 552 reduces the electric field at the surface of the substrate 522 between the gate structures 548 and a source/drain contact, which enables a lower peak electric field strength to be achieved than without the RPO layer 552. The lower peak electric field strength enables the ESD protection circuits 502, 504, and/or 506 to handle higher voltages (e.g., stronger ESD events) without experiencing breakdown. Alternatively, the RPO layer 552 may be omitted to achieve higher on current (Iₒₙ).

As indicated above, FIGS. 5A-5C are provided as examples. Other examples may differ from what is described with regard to FIGS. 5A-5C.

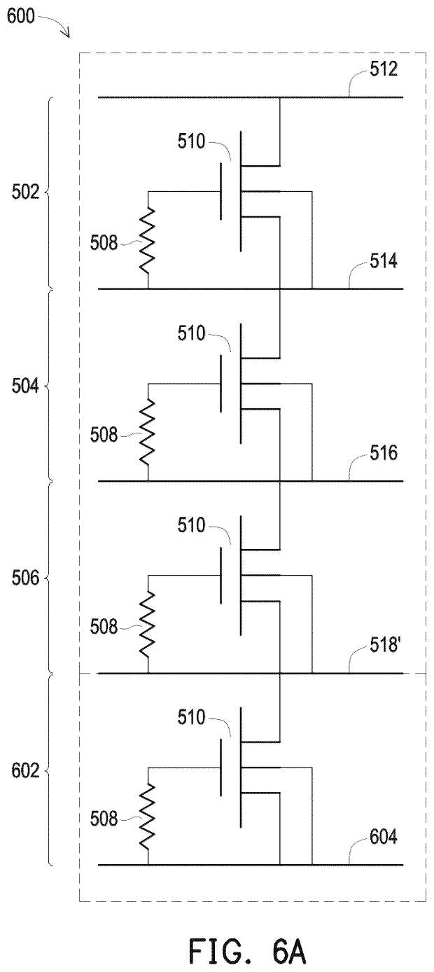

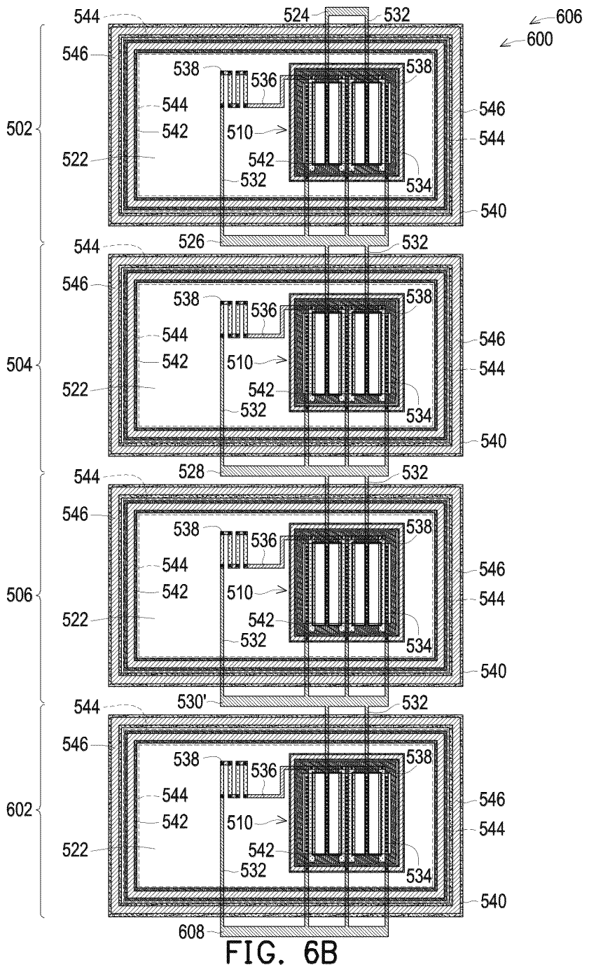

FIG. 6A is a diagram of an example semiconductor device 600 described herein. FIG. 6B is a diagram of an example implementation 606 of a layout of the semiconductor device 600 described herein. As shown in FIGS. 6A and 6B, the example semiconductor device 600 may include a similar arrangement of circuits as the example semiconductor device 500 illustrated and described in connection with FIGS. 5A-5C. For example, the example semiconductor device 600 may include components 502-516, 522-528, and 532-552. The example semiconductor device may further include an additional ESD protection circuit 602 at the end of the stacked arrangement of ESD protection circuits 502, 504, and 506. The additional ESD protection circuit 602 results in a third shared voltage source 518′ between the ESD protection circuit 506 and the additional ESD protection circuit 602, a conductive structure 530′ corresponding to the third shared voltage source 518′, and a ground voltage source 604.

Like the ESD protection circuits 502, 504, and 506, the additional ESD protection circuit 602 includes a ggNMOS circuit with the same arrangement as the gg NMOS circuits of the ESD protection circuits 502, 504, and 506. For example, the additional ESD protection circuit 602 includes a resistor 108 and a ggNMOS transistor 510.

As noted above, in a non-limiting example, each of the multiple stacked ESD protection circuits 502, 504, and 506 may be biased in a range of approximately 8 volts to approximately 10 volts, instead of a single high voltage ESD circuit being biased at approximately 24 to approximately 30 volts, or at a higher voltage. The ESD protection circuits 502, 504, and 506 may include transistors with thinner gate dielectric layers and correspondingly lower threshold voltages than the gate dielectric layers and threshold voltages of the transistors of the high voltage ESD protection circuits.

In some implementations, each of the multiple stacked ESD protection circuits 502, 504, and 506 is biased at the same voltage. For example, assuming that each of the multiple stacked ESD protection circuits 502, 504, and 506 is biased at 9 volts, the total bias of the ESD protection circuits 502, 504, and 506 would be 9*3 or 27 volts. In a case where a required bias voltage is greater than 27 volts (e.g., 28 volts), an additional ESD protection circuit having a lower bias voltage than that of the ESD protection circuits 502, 504, and 506 is added to the stacked arrangement to achieve the required total bias voltage. For example, in the case of the semiconductor device 600, the additional ESD protection circuit 602 has a lower bias than that of the ESD protection circuits 502, 504, and 506. Keeping with the non-limiting operational example of a bias of 28 volts, in this case, the additional ESD protection circuit 602 may have a bias voltage of 1 volt, so that the total bias voltage for the ESD protection circuits 502, 504, 506, and 602 is (9*3)+1=28 volts. The additional ESD protection circuit 602, which may be referred to as a “low voltage ESD protection circuit” due to its lower bias voltage than that of the ESD protection circuits 502, 504, and 506, may include transistors with thinner gate dielectric layers and correspondingly lower threshold voltages than the gate dielectric layers and threshold voltages of the transistors of the ESD protection circuits 502, 504, and 506. The ESD protection circuits 502, 504, and 506 may be referred to as “middle voltage ESD protection circuits” due to their higher bias voltage than the bias voltage of the low voltage ESD protection circuit, and lower bias voltage than the bias voltage of a high voltage ESD protection circuit.

The operation of the ESD protection circuits 502, 504, and 506 in the semiconductor device 600 proceeds in a similar manner to that of the ESD protection circuits 502, 504, and 506 in the semiconductor device 500, except that following the activation of the ggNMOS transistor 510 of the ESD protection circuit 506, instead of being transmitted to the ground voltage source, further dissipated voltage corresponding to a portion of the original voltage inputted to the supply voltage source 512 is transmitted from the source/drain region of the ggNMOS transistor 510 of the ESD protection circuit 506 to the third shared voltage source 518′, which activates the additional ESD protection circuit 602 in a similar manner to the ESD protection circuits 502, 504, and 506. In more detail, the dissipated voltage applied to the third shared voltage source 518′ causes the parasitic capacitance of the additional ESD protection circuit 602 to be shorted. As a result, the ggNMOS transistor 510 of the additional ESD protection circuit 602 is turned on. The ggNMOS transistor 510 of the additional ESD protection circuit 602 is turned on because the Vgs resulting from the dissipated voltage inputted to the third shared voltage source 518′ is greater than the Vt of the ggNMOS transistor 510 of the ESD protection circuit 506. Due to the activation of the ggNMOS transistor 510 of the additional ESD protection circuit 602, a final dissipated voltage corresponding to a portion of the original voltage inputted to the supply voltage source 512 is transmitted from the source/drain region of the ggNMOS transistor 510 of the additional ESD protection circuit 602 to the ground voltage source 604.

As shown in FIG. 6B, in the example implementation 606, the layout of the ESD protection circuits 502, 504, and 506 in the semiconductor device 600 is the same as the layout of the ESD protection circuits 502, 504, and 506 in the semiconductor device 500. However, due to the additional ESD protection circuit 602, a conductive structure 530′ at the bottom side of the ESD protection circuit 506 corresponds to the third shared voltage source 518′ instead of a ground voltage source. The conductive structure 530′ is similar to the conductive structures 526 and 528, which respectively correspond to the first and second shared voltage sources 514 and 516.

The additional ESD circuit 602 has the same layout as that of the ESD protection circuits 502, 504, and 506, except that in the additional ESD protection circuit 602, a first source/drain region of the ggNMOS transistor 510 is connected to the third shared voltage source 518′ through the conductive structure 530′. Also, in the additional ESD protection circuit 602, the resistor 108 and the gate and a second source/drain region of the ggNMOS transistor 510 are connected (e.g., electrically coupled) to the ground voltage source 604 through the conductive structure 608.

As indicated above, FIGS. 6A and 6B are provided as examples. Other examples may differ from what is described with regard to FIGS. 6A and 6B.

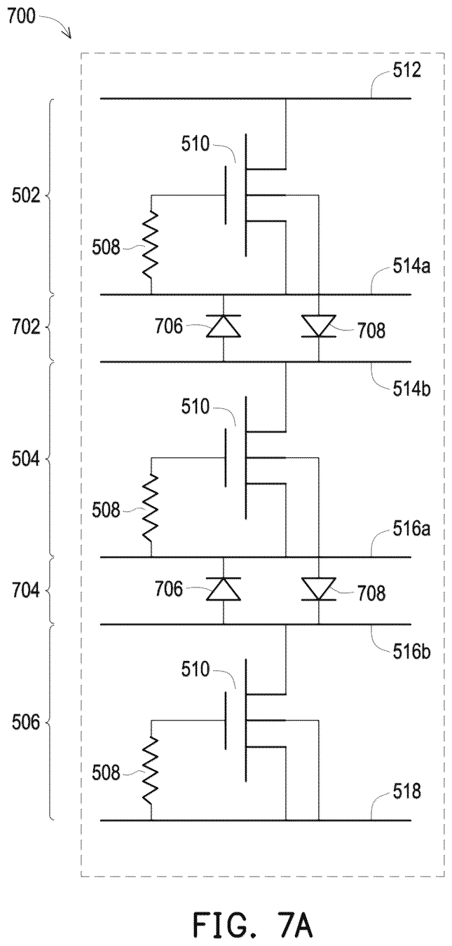

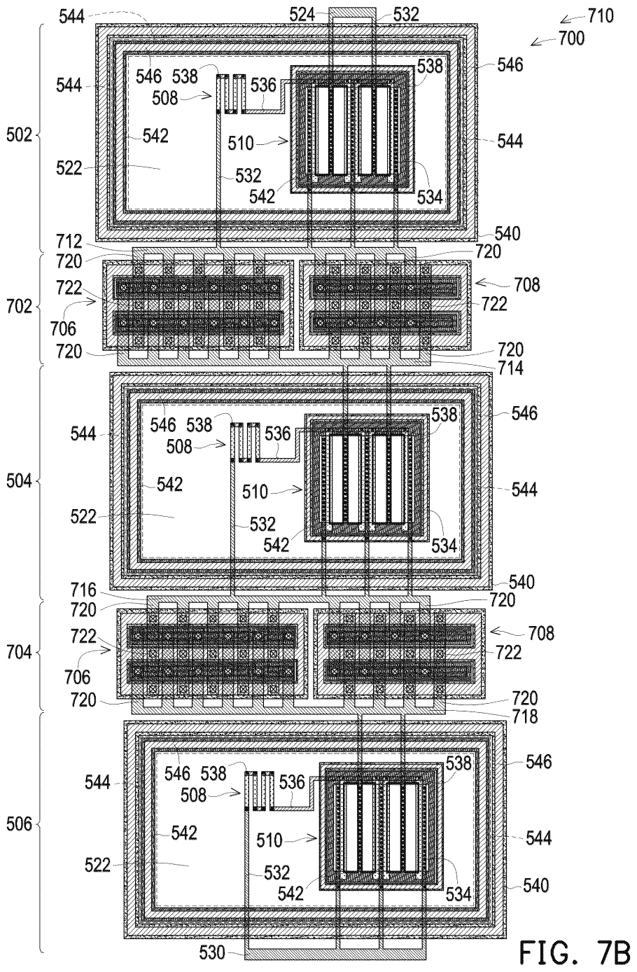

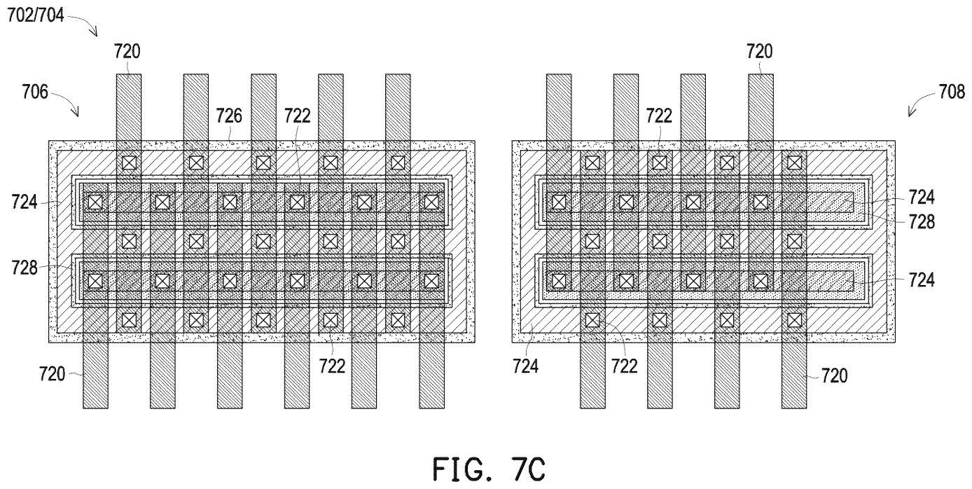

FIG. 7A is a diagram of an example semiconductor device 700 described herein. FIG. 7B is a diagram of an example implementation 710 of a layout of the semiconductor device 700 described herein. As shown in FIGS. 7A and 7B, the example semiconductor device 700 may include a similar arrangement of circuits as the example semiconductor device 500 illustrated and described in connection with FIGS. 5A-5C. For example, the example semiconductor device 700 may include components 502-512, 518, 522, 524, and 530-552. The example semiconductor device 700 may further include B2B diode structures 702 and 704 in the stacked arrangement between ESD protection circuits 502 and 504, and between ESD protection circuits 504 and 506. The B2B diode structures 702 and 704 each include a first diode 706 and a second diode 708. Each first diode 706 conducts current in a first direction, and each second diode 708 conducts current in a second direction opposite the first direction. For example, the first diode 706 in the B2B diode structure 702 conducts current from the ESD protection circuit 504 to the ESD protection circuit 502, and the second diode 708 in the B2B diode structure 702 conducts current from the ESD protection circuit 502 to the ESD protection circuit 504. Similarly, in the B2B diode structure 704, the first diode 706 conducts current from the ESD protection circuit 506 to the ESD protection circuit 504, and the second diode 708 conducts current from the ESD protection circuit 504 to the ESD protection circuit 506.

In the semiconductor device 700, the first and second diodes 706 and 708 of the B2B diode structure 702 are connected between a first mid-level voltage source 514a and a second mid-level voltage source 514b, and the first and second diodes 706 and 708 of the B2B diode structure 704 are connected between a third mid-level voltage source 516a and a fourth mid-level voltage source 516b. In more detail, in the B2B diode structure 702, the cathode and the anode of the first diode 706 are respectively connected to the first mid-level voltage source 514a and to the second mid-level voltage source 514b, and the cathode and the anode of the second diode 708 are respectively connected to the second mid-level voltage source 514b and to the first mid-level voltage source 514a. In the B2B diode structure 704, the cathode and the anode of the first diode 706 are respectively connected to the third mid-level voltage source 516a and to the fourth mid-level voltage source 516b, and the cathode and the anode of the second diode 708 are respectively connected to the fourth mid-level voltage source 516b and to the third mid-level voltage source 516a. Each of the B2B diode structures 702 and 704 permits current to flow in a particular direction when the applied voltage to a first diode 706 or a second diode 708 exceeds a diode's breakdown voltage.

The ESD protection circuit 502 is connected between the supply voltage source 512 and the first mid-level voltage source 514a. In the ESD protection circuit 502, a first source/drain region of the ggNMOS transistor 510 is connected to the supply voltage source 122. The resistor 508, and the gate and a second source/drain region of the ggNMOS transistor 510, are connected to the first mid-level voltage source 514a.

The ESD protection circuit 104 is connected between the second mid-level voltage source 514b and the third mid-level voltage source 516a. In the ESD protection circuit 504, a first source/drain region of the ggNMOS transistor 510 is connected to the second mid-level voltage source 514b. The resistor 508, and a gate and a second source/drain region of the ggNMOS transistor 510, are connected to the third mid-level voltage source 516a.

The ESD protection circuit 106 is connected between the fourth mid-level voltage source 516b and the ground voltage source 518. In the ESD protection circuit 506, a first source/drain region of the ggNMOS transistor 510 is connected to the fourth mid-level voltage source 516b. The resistor 508, and a gate and a second source/drain region of the ggNMOS transistor 510, are connected to the ground voltage source 518.

The second source/drain region of the ggNMOS transistor 510 of the ESD protection circuit 502 is electrically coupled to the first source/drain region of the ggNMOS transistor 510 of the ESD protection circuit 504 through the first mid-level voltage source 514a, through the B2B diode structure 702 (e.g., through the first diode 706 and/or the second diode 708), and through the second mid-level voltage source 514b.

The second source/drain region of the ggNMOS transistor 510 of the ESD protection circuit 504 is electrically coupled to the first source/drain region of the ggNMOS transistor 510 of the ESD protection circuit 506 through the third mid-level voltage source 516a, through the B2B diode structure 704 (e.g., through the first diode 706 and/or the second diode 708), and through the fourth mid-level voltage source 516b.

The operation of the ESD protection circuits 502, 504, and 506 in the semiconductor device 700 proceeds in a similar manner to that of the ESD protection circuits 502, 504, and 506 in the semiconductor device 500, except that following the activation of the ggNMOS transistor 510 of the ESD protection circuit 502, dissipated voltage corresponding to the voltage inputted to the supply voltage source 512 is transmitted from the source/drain region of the ggNMOS transistor 510 of the ESD protection circuit 102 to the first mid-level voltage source 514a, through the second diode 708 of the B2B diode structure 702, and to the second mid-level voltage source 514b, which activates the ESD protection circuit 504 in a similar manner to the ESD protection circuit 502. In more detail, the dissipated voltage applied to the second mid-level voltage source 514b causes the parasitic capacitance of the ESD protection circuit 504 to be shorted. As a result, the ggNMOS transistor 510 of the ESD protection circuit 504 is turned on. The ggNMOS transistor 510 of the ESD protection circuit 504 is turned on because the Vgs resulting from the dissipated voltage inputted to the second mid-level voltage source 514b is greater than the Vt of the ggNMOS transistor 510 of the ESD protection circuit 504.

Due to the activation of the ggNMOS transistor 510 of the ESD protection circuit 504, further dissipated voltage corresponding to a portion of the original voltage inputted to the supply voltage source 512 is transmitted from the source/drain region of the ggNMOS transistor 510 of the ESD protection circuit 504 to the third mid-level voltage source 516a, through the second diode 708 of the B2B diode structure 704, and to the fourth mid-level voltage source 516b, which activates the ESD protection circuit 506 in a similar manner to the ESD protection circuits 502 and 504. In more detail, the dissipated voltage applied to the fourth mid-level voltage source 516b causes the parasitic capacitance of the ESD protection circuit 506 to be shorted. As a result, the ggNMOS transistor 510 of the ESD protection circuit 506 is turned on. The ggNMOS transistor 510 of the ESD protection circuit 506 is turned on because the Vgs resulting from the dissipated voltage inputted to the fourth mid-level voltage source 516b is greater than the Vt of the ggNMOS transistor 510 of the ESD protection circuit 506. Due to the activation of the ggNMOS transistor 510 of the ESD protection circuit 506, a final dissipated voltage corresponding to a portion of the original voltage inputted to the supply voltage source 512 is transmitted from the source/drain region of the ggNMOS transistor 510 of the ESD protection circuit 506 to the ground voltage source 518.

As noted herein, in some implementations, each of the multiple stacked ESD protection circuits 502, 504, and 506 is biased at the same voltage. For example, assuming that each of the multiple stacked ESD protection circuits 502, 504, and 506 is biased at 9 volts, the total bias of the ESD protection circuits 502, 504, and 506 would be 9*3 or 27 volts. In a case where a required bias voltage is greater than 27 volts (e.g., 28 volts), the B2B diode structures 702 and 702, each having a lower bias voltage than that of the ESD protection circuits 502, 504, and 506, are added to the stacked arrangement to achieve the required total bias voltage. For example, in the case of the semiconductor device 700, the B2B diode structures 702 and 702 may each have a bias voltage of 0.5 volts, so that the total bias voltage for the ESD protection circuits 502, 504, 506, and the B2B diode structures 702 and 704 is (9*3)+(2*0.5)=28 volts.

As shown in FIG. 7B, in the example implementation 710, the layout of the ESD protection circuits 502, 504, and 506 in the semiconductor device 700 is the same as the layout of the ESD protection circuits 502, 504, and 506. However, due to the addition of the B2B diode structures 702 and 704, a conductive structure 712 at the bottom side of the ESD protection circuit 502 corresponds to the first mid-level voltage source 514a, the conductive structure 714 at the top side of the ESD protection circuit 504 corresponds to the second mid-level voltage source 514b, the conductive structure 716 at the bottom side of the ESD protection circuit 504 corresponds to the third mid-level voltage source 516a, and the conductive structure 718 at the top side of the ESD protection circuit 506 corresponds to the fourth mid-level voltage source 516b. The conductive structure 530 corresponds to the ground voltage source 518. The conductive structures 712-718 are similar to the conductive structures 526, 528 and 530.

The first and second diodes 706 and 708 of the B2B diode structure 702 are electrically coupled to the conductive structures 712 and 714 through conductive structures 720 and 722, and the first and second diodes 706 and 708 of the B2B diode structure 704 are electrically coupled to the conductive structures 716 and 718 through conductive structures 720 and 722. The conductive structures 712-720 may be metallization level type conductive structures (e.g., trenches, conductive lines), and the conductive structures 722 may be interconnect type conductive structures (e.g., vias).

FIG. 7C illustrates an enlarged view of the layout of the B2B diode structures 702 and 704. As shown in FIG. 7C, each of the first and second diodes 706 and 708 includes an active area defining region 724, p+ regions 726, and n+ regions 728. Similar to the active area defining regions 546, the active area defining region 724 defines an area in which active regions of different components of the first and second diodes 706 and 708 (e.g., anodes, cathodes, pn junctions) are included. The p+ regions 726 (e.g., p-type regions) may be regions of a substrate that are doped with one or more p-type dopants, such as boron (B), gallium (Ga), and/or indium (In), among other examples. The n+ regions 728 (e.g., n-type regions) may be regions of a substrate that are doped with one or more n-type dopants, such as phosphorous (P), arsenic (As), bismuth (Bi), and/or antimony (Sb), among other examples.

As indicated above, FIGS. 7A-7C are provided as examples. Other examples may differ from what is described with regard to FIGS. 7A-7C.

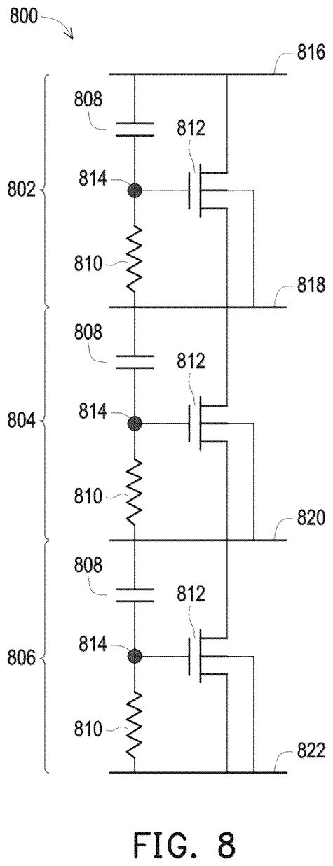

FIG. 8 is a diagram of an example semiconductor device 800 described herein. The semiconductor device 800 may include a logic device (e.g., a processor, CPU, a GPU), a memory device (e.g., a DRAM device, an SRAM device), a display panel device (e.g., a display panel driver including a driver IC, a line driver IC, a level shifter IC), and/or another type of semiconductor device 800 that includes high voltage semiconductor devices.

An example semiconductor device 800 may include a device circuit, and a plurality of ESD protection circuits 802, 804, and 806, among other types of circuits. In some implementations, the device circuit includes a high voltage device circuit and high voltage transistors. A high voltage transistor may include a high voltage planar transistor, a high voltage finFET, a high voltage nanostructure (e.g., a GAA transistor, a nanowire transistor, a nanosheet transistor, a multi-bridge channel transistor, a nanoribbon transistor), and/or another type of high voltage transistor that is configured to operate at high voltages (e.g., greater than 40 volts, for example).

Like the ESD protection circuits 502, 504, and 506, the ESD protection circuits 802, 804, and 806 may each include a grounded-gate metal-oxide semiconductor circuit (e.g., a ggNMOS circuit) that is configured to provide ESD protection for the device circuit against high voltage spikes, high voltage surges, and/or other types of high voltage events.

The ESD protection circuits 802, 804, and 806 are similar to the ESD protection circuits 502, 504, and 506, except that in the example semiconductor device 800, each ESD protection circuit 802, 804, and 806 is a ggNMOS circuit including a capacitor 808 in addition to a resistor 810 and a ggNMOS transistor 812. The ggNMOS transistor 812 may be a large width FET having an active region with a width the same as, or substantially the same as, the width WD1 of the second ggNMOS transistor 116.

The capacitor 808 of the ESD protection circuits 802, 804, and 806 is connected in series with resistor 810. The capacitor 808 and the resistor 810 are connected to the gate of the ggNMOS transistor 812 through a node 814 disposed between the capacitor 808 and the resistor 810.

The ESD protection circuit 802 is connected to a supply voltage source 816, providing a positive supply voltage (e.g., drain voltage (VDD)) to the ESD protection circuit 802. The ESD protection circuit 802 and the ESD protection circuit are connected to a first shared voltage source 818, where an output voltage of the ESD protection circuit 802 is provided to the ESD protection circuit 804 as a supply voltage. The ESD protection circuit 804 and the ESD protection circuit 806 are connected to a second shared voltage source 820, where an output voltage of the ESD protection circuit 804 is provided to the ESD protection circuit 806 as a supply voltage. The ESD protection circuit 806 is connected to a ground (e.g., negative supply voltage) voltage source 822.

The ESD protection circuits 802, 804, and 806 are interconnected in a stacked arrangement, where the ESD protection circuits 802, 804, and 806 are connected to each other and connected between the supply voltage source 816 and the ground voltage source 822. The ESD protection circuits 802, 804, and 806 operate in a similar manner to the ESD protection circuits 502, 504, and 506 of the example semiconductor device 500, except that in the example semiconductor device 800, instead of a parasitic capacitance being shorted to lead to ggNMOS transistor activation in each of the ESD protection circuits 802, 804, and 806, shorting of the capacitor 808 causes the activation of the ggNMOS transistor 812 in each of the ESD protection circuits 802, 804, and 806. For example, when an input voltage satisfying a threshold to qualify for an ESD event (e.g., a voltage satisfying a BV) is applied to the supply voltage source 816, the capacitor 808 is shorted. As a result, the ggNMOS transistor 812 of the ESD protection circuit 802 is turned on. The ggNMOS transistor 812 of the ESD protection circuit 802 is turned on because the Vgs resulting from the input voltage to the supply voltage source 816 is greater than the Vt of the ggNMOS transistor 812 of the ESD protection circuit 802.

Due to the activation of the ggNMOS transistor 812 of the ESD protection circuit 802, dissipated voltage corresponding to the voltage inputted to the supply voltage source 816 is transmitted from the source/drain region of the ggNMOS transistor 812 of the ESD protection circuit 802 to the first shared voltage source 818, which activates the ESD protection circuit 804 in a similar manner to the ESD protection circuit 802. In more detail, the dissipated voltage applied to the first shared voltage source 818 causes the capacitor 808 of the ESD protection circuit 804 to be shorted. As a result, the ggNMOS transistor 812 of the ESD protection circuit 804 is turned on. The ggNMOS transistor 812 of the ESD protection circuit 804 is turned on because the Vgs resulting from the dissipated voltage inputted to the first shared voltage source 818 is greater than the Vt of the ggNMOS transistor 812 of the ESD protection circuit 804.

Due to the activation of the ggNMOS transistor 812 of the ESD protection circuit 804, further dissipated voltage corresponding to a portion of the original voltage inputted to the supply voltage source 816 is transmitted from the source/drain region of the ggNMOS transistor 812 of the ESD protection circuit 804 to the second shared voltage source 820, which activates the ESD protection circuit 806 in a similar manner to the ESD protection circuits 802 and 804. In more detail, the dissipated voltage applied to the second shared voltage source 820 causes the capacitor 808 of the ESD protection circuit 806 to be shorted. As a result, the ggNMOS transistor 812 of the ESD protection circuit 806 is turned on. The ggNMOS transistor 812 of the ESD protection circuit 806 is turned on because the Vgs resulting from the dissipated voltage inputted to the second shared voltage source 820 is greater than the Vt of the ggNMOS transistor 812 of the ESD protection circuit 806. Due to the activation of the ggNMOS transistor 812 of the ESD protection circuit 806, a final dissipated voltage corresponding to a portion of the original voltage inputted to the supply voltage source 816 is transmitted from the source/drain region of the ggNMOS transistor 812 of the ESD protection circuit 806 to the ground voltage source 822.

The multiple stacked ESD protection circuits 802, 804, and 806 may each be biased at a lower voltage than a single high voltage ESD protection circuit. In a non-limiting example, each of the multiple stacked ESD protection circuits 802, 804, and 806 may be biased in a range of approximately 8 volts to approximately 10 volts, instead of a single high voltage ESD circuit being biased at approximately 24 to approximately 30 volts, or at a higher voltage. Depending upon a required total bias value of the plurality of ESD protection circuits (e.g., ESD protection circuits 802, 804, and 806), the number of ESD protection circuits in a stacked arrangement may vary. For example, in some implementations, the number of ESD protection circuits in a stacked arrangement may vary from 3 to 6.

As indicated above, FIG. 8 is provided as an example. Other examples may differ from what is described with regard to FIG. 8.

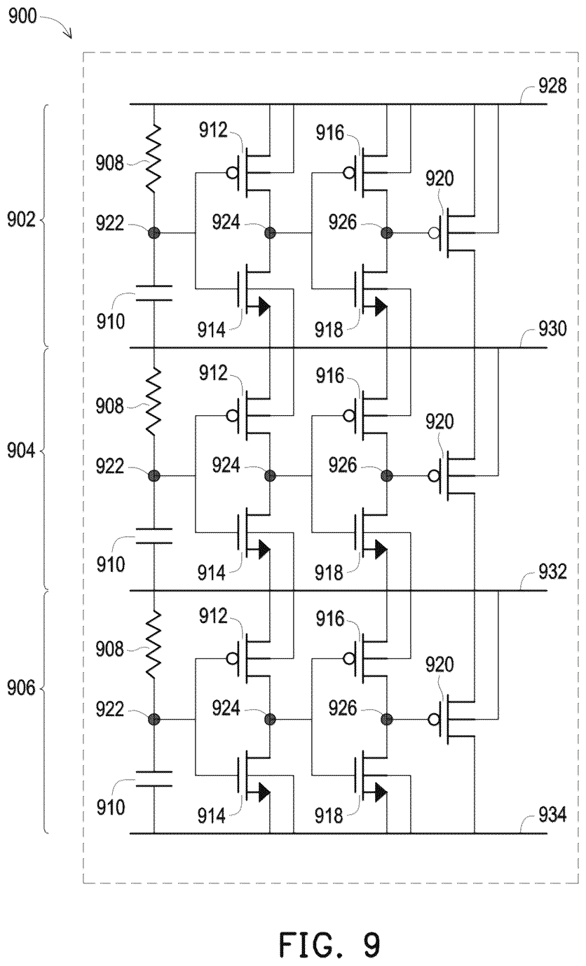

FIG. 9 is a diagram of an example semiconductor device 900 described herein. The semiconductor device 900 may include a logic device (e.g., a processor, CPU, a GPU), a memory device (e.g., a DRAM device, an SRAM device), a display panel device (e.g., a display panel driver including a driver IC, a line driver IC, a level shifter IC), and/or another type of semiconductor device 900 that includes high voltage semiconductor devices.

An example semiconductor device 900 may include a device circuit, and a plurality of ESD protection circuits 902, 904, and 906, among other types of circuits. In some implementations, the device circuit includes a high voltage device circuit and high voltage transistors. A high voltage transistor may include a high voltage planar transistor, a high voltage finFET, a high voltage nanostructure (e.g., a GAA transistor, a nanowire transistor, a nanosheet transistor, a multi-bridge channel transistor, a nanoribbon transistor), and/or another type of high voltage transistor that is configured to operate at high voltages (e.g., greater than 40 volts, for example).

Like the ESD protection circuits 102, 104, and 106 in the semiconductor device 100, the ESD protection circuits 902, 904, and 906 may each be a clamp circuit including a resistor 908, a capacitor 910, a first gdPMOS transistor 912, and a first ggNMOS transistor 914. The first gdPMOS transistor 912 and the first ggNMOS transistor 914 form a first inverter with a high-side p-type transistor (e.g., first gdPMOS transistor 912) and a low-side n-type transistor (e.g., first ggNMOS transistor 914). Unlike the ESD protection circuits 102, 104, and 106, each of the ESD protection circuits 902, 904, and 906 further includes a second inverter formed from a second gdPMOS transistor 916, and a second ggNMOS transistor 918. In addition, each of the ESD protection circuits 902, 904, and 906 further includes a third gdPMOS transistor 920. Like the second ggNMOS transistor 116 of the ESD protection circuits 102, 104, and 106 in the semiconductor device 100, the third gdPMOS transistor 920 is a large width FET, having an active region with a larger width than the active region width of the first ggNMOS transistor 114.

A node 922 between the resistor 108 and the capacitor 110 is connected to gates of the first gdPMOS transistor 912 and of the first ggNMOS transistor 914. A node 924 is connected between source/drain regions of each of the first gdPMOS transistor 912 and the first ggNMOS transistor 914 and is connected to gates of the second gdPMOS transistor 916 and of the second ggNMOS transistor 918. A node 926 is connected between source/drain regions of each of the second gdPMOS transistor 916 and of the second ggNMOS transistor 918. The node 926 is connected to a gate of the third gdPMOS transistor 920.

The ESD protection circuit 902 is connected to a supply voltage source 928, providing a positive supply voltage (e.g., drain voltage (VDD)) to the ESD protection circuit 902. The

ESD protection circuit 902 and the ESD protection circuit 904 are connected to a first shared voltage source 930, where an output voltage of the ESD protection circuit 902 is provided to the ESD protection circuit 904 as a supply voltage. The ESD protection circuit 904 and the ESD protection circuit 906 are connected to a second shared voltage source 932, where an output voltage of the ESD protection circuit 904 is provided to the ESD protection circuit 906 as a supply voltage. The ESD protection circuit 906 is connected to a ground (e.g., negative supply voltage) voltage source 934.

The ESD protection circuits 902, 904, and 906 are interconnected in a stacked arrangement, where the ESD protection circuits 902, 904, and 906 are connected to each other and connected between the supply voltage source 928 and the ground voltage source 934. In more detail, a gate and a source/drain region of each of the first, second, and third gdPMOS transistors 912, 916, and 920 of the ESD protection circuit 902 are connected to the supply voltage source 928. A gate and a source/drain region of each the first ggNMOS transistor 914 and the second ggNMOS transistor 918 of the ESD protection circuit 902 are connected to the first shared voltage source 930. A source/drain region of the third gdPMOS transistor 920 of the ESD protection circuit 902 is connected to the first shared voltage source 930. The resistor 908 of the ESD protection circuit 902 is connected to the supply voltage source 928, and the capacitor 910 of the ESD protection circuit 902, which is connected in series with resistor 908 of the ESD protection circuit 902, is further connected to the first shared voltage source 930.

A gate and a source/drain region of each of the first, second, and third gdPMOS transistors 912, 916, and 920 of the ESD protection circuit 904 are connected to the first shared voltage source 930. A gate and a source/drain region of each the first ggNMOS transistor 914 and the second ggNMOS transistor 918 of the ESD protection circuit 904 are connected to the second shared voltage source 932. A source/drain region of the third gdPMOS transistor 920 of the ESD protection circuit 904 is connected to the second shared voltage source 932. The resistor 908 of the ESD protection circuit 904 is connected to the first shared voltage source 930, and the capacitor 910 of the ESD protection circuit 904, which is connected in series with resistor 908 of the ESD protection circuit 904, is further connected to the second shared voltage source 932.

A gate and a source/drain region of each of the first, second, and third gdPMOS transistors 912, 916, and 920 of the ESD protection circuit 906 are connected to the second shared voltage source 932. A gate and a source/drain region of each the first ggNMOS transistor 914 and the second ggNMOS transistor 918 of the ESD protection circuit 906 are connected to the ground voltage source 934. A source/drain region of the third gdPMOS transistor 920 of the ESD protection circuit 906 is connected to the ground voltage source 934. The resistor 908 of the ESD protection circuit 902 is connected to the second shared voltage source 932, and the capacitor 910 of the ESD protection circuit 902, which is connected in series with resistor 908 of the ESD protection circuit 906, is further connected to the ground voltage source 934.

In operation, in the ESD protection circuit 902, when an input voltage satisfying a threshold to qualify for an ESD event (e.g., a voltage satisfying a BV) is applied to the supply voltage source 928, the capacitor 910 is shorted. As a result, the first gdPMOS transistor 912 is turned on, while the first ggNMOS transistor 914 is off. The first gdPMOS transistor 912 is turned on because the Vgs resulting from the input voltage to the supply voltage source 928 is greater than the Vt of the first gdPMOS transistor 912. The activation of the first gdPMOS transistor 912 causes the inverter including the second gdPMOS transistor 916 and the second ggNMOS transistor 918 to receive a voltage approximately equal to the input voltage to the supply voltage source 928. As a result, similar to the operation of the first gdPMOS transistor 912, the second gdPMOS transistor 916 is turned on, while the first ggNMOS transistor 914 is off. The second gdPMOS transistor 916 is turned on because the Vgs is greater than the Vt of the second gdPMOS transistor 916. The activation of the second gdPMOS transistor 916 causes the gate of the third gdPMOS transistor 920 to receive a voltage approximately equal to the supply voltage. As a result, the third gdPMOS transistor 920 is turned on because the Vgs is greater than the Vt of the third gdPMOS transistor 920.

Due to the activation of the third gdPMOS transistor 920 of the ESD protection circuit 902, dissipated voltage corresponding to the voltage inputted to the supply voltage source 928 is transmitted from the source/drain region of the third gdPMOS transistor 920 of the ESD protection circuit 902 to the first shared voltage source 930, which activates the ESD protection circuit 904 in a similar manner to the ESD protection circuit 902. In more detail, in the ESD protection circuit 904, the dissipated voltage applied to the first shared voltage source 930 causes the capacitor 910 of the ESD protection circuit 904 to be shorted. As a result, the first gdPMOS transistor 912 is turned on, while the first ggNMOS transistor 914 is off. The first gdPMOS transistor 912 is turned on because the Vgs resulting from the input voltage to the first shared voltage source 930 is greater than the Vt of the first gdPMOS transistor 912. The activation of the first gdPMOS transistor 912 causes the inverter including the second gdPMOS transistor 916 and the second ggNMOS transistor 918 to receive a voltage approximately equal to the input voltage to the first shared voltage source 930. As a result, similar to the operation of the first gdPMOS transistor 912, the second gdPMOS transistor 916 is turned on, while the first ggNMOS transistor 914 is off. The second gdPMOS transistor 916 is turned on because the Vgs is greater than the Vt of the second gdPMOS transistor 916. The activation of the second gdPMOS transistor 916 causes the gate of the third gdPMOS transistor 920 to receive a voltage approximately equal to the input voltage to the first shared voltage source 930. As a result, the third gdPMOS transistor 920 is turned on because the Vgs is greater than the Vt of the third gdPMOS transistor 920.

Due to the activation of the third gdPMOS transistor 920 of the ESD protection circuit 904, further dissipated voltage corresponding to a portion of the original voltage inputted to the supply voltage source 928 is transmitted from the source/drain region of the third gdPMOS transistor 920 of the ESD protection circuit 904 to the second shared voltage source 932, which activates the ESD protection circuit 906 in a similar manner to the ESD protection circuits 902 and 904. In more detail, the dissipated voltage applied to the second shared voltage source 932 causes the capacitor 910 of the ESD protection circuit 906 to be shorted. As a result, in the ESD protection circuit 906, the first gdPMOS transistor 912 is turned on, while the first ggNMOS transistor 914 is off. The first gdPMOS transistor 912 is turned on because the Vgs resulting from the input voltage to the second shared voltage source 932 is greater than the Vt of the first gdPMOS transistor 912. The activation of the first gdPMOS transistor 912 causes the inverter including the second gdPMOS transistor 916 and the second ggNMOS transistor 918 to receive a voltage approximately equal to the input voltage to the second shared voltage source 932. As a result, similar to the operation of the first gdPMOS transistor 912, the second gdPMOS transistor 916 is turned on, while the first ggNMOS transistor 914 is off. The second gdPMOS transistor 916 is turned on because the Vgs is greater than the Vt of the second gdPMOS transistor 916. The activation of the second gdPMOS transistor 916 causes the gate of the third gdPMOS transistor 920 to receive a voltage approximately equal to the input voltage to the second shared voltage source 932. As a result, the third gdPMOS transistor 920 is turned on because the Vgs is greater than the Vt of the third ggNMOS transistor 920. Due to the activation of the third gdPMOS transistor 920 of the ESD protection circuit 904, further dissipated voltage corresponding to a portion of the original voltage inputted to the supply voltage source 928 is transmitted from the source/drain region of the third gdPMOS transistor 920 of the ESD protection circuit 904 to the ground voltage source 934.

The multiple stacked ESD protection circuits 902, 904, and 906 may each be biased at a lower voltage than a single high voltage ESD protection circuit. In a non-limiting example, each of the multiple stacked ESD protection circuits 902, 904, and 906 may be biased in a range of approximately 8 volts to approximately 10 volts, instead of a single high voltage ESD circuit being biased at approximately 24 to approximately 30 volts, or at a higher voltage. Depending upon a required total bias value of the plurality of ESD protection circuits (e.g., ESD protection circuits 902, 904, and 906), the number of ESD protection circuits in a stacked arrangement may vary. For example, in some implementations, the number of ESD protection circuits in a stacked arrangement may vary from 3 to 6.

As indicated above, FIG. 9 is provided as an example. Other examples may differ from what is described with regard to FIG. 9.

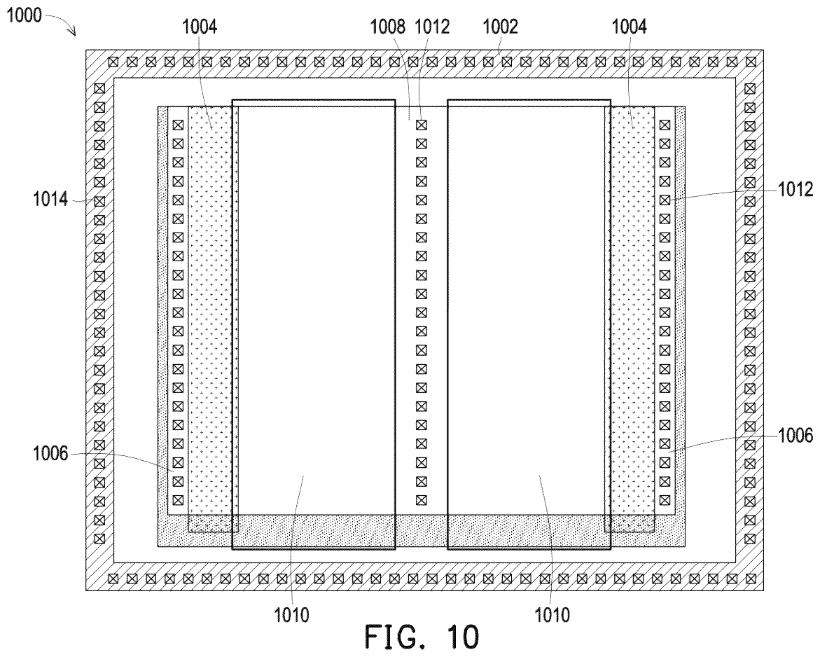

FIG. 10 is a diagram of an example implementation 1000 of a transistor described herein. As shown in FIG. 10, similar to the ggNMOS transistor 510 shown in FIGS. 5B and 5C, one or more of the transistors used in the ESD protection circuits described in connection with the semiconductor devices 100 and 300-900 include an active area defining region 1002, a plurality of gate structures 1004, source/drain regions 1006 (e.g., source regions), a source/drain region 1008 (e.g., a drain region), and RPO layers 1010 on portions of the source/drain region 1008. Contacts 1012 (e.g., interconnect structures) are formed on the source/drain regions 1006 and 1008, and contacts 1014 (e.g., interconnect structures) are formed in the active area defining region 1002.

As indicated above, FIG. 10 is provided as an example. Other examples may differ from what is described with regard to FIG. 10.

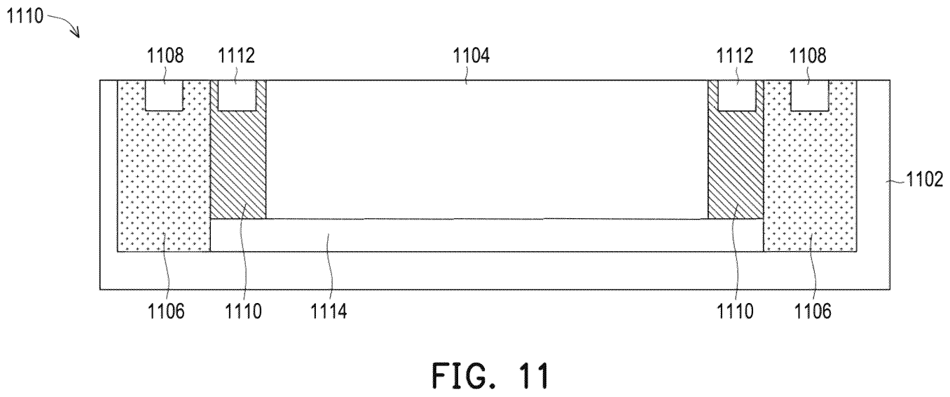

FIG. 11 is a diagram of an example implementation 1100 of a semiconductor device described herein. In the stacked arrangements of the ESD protection circuits described in connection with the semiconductor devices 100 and 300-900, each ESD protection circuit in a stacked arrangement (e.g., each ESD protection circuit 102, 104, 106, each ESD protection circuit 502, 504, 506, etc.) includes an isolation structure disposed around an ESD protection circuit and/or separating adjacent ESD circuits.

As shown in the example implementation 1100, a substrate 1102 includes a device region 1104 formed in and/or on the substrate 1102. The device region 1104 includes, for example, an ESD protection circuit. A p-doped well region 1106 including p+ regions 1108 is formed in an outer portion of the substrate 1102 around the device region 1104, and around an n-doped well region 1110 including n+ regions 1112. The n-doped well region 1110 including the n+ regions 1112 is formed in the substrate 1102 between the device region 1104 and the p-doped well region 1106. A deep n-well barrier region 1114 is formed under the device region 1104, under the n-doped well region 1110, and between portions of the p-doped well region 1106 including the p+ regions 1108. The p-doped well region 1106 including the p+ regions 1108, the n-doped well region 1110 including the n+ regions 1112, and the deep n-well barrier region 1114 form the isolation structure around the device region 1104 (e.g., around one of the ESD protection circuits 102, 104, 106, 502, 504, 506, etc.).

The substrate 1102 may be similar to the substrates 132 and 522, and may be, for example, a p-type substrate. The p-doped well region 1106 may include regions of the substrate 1102 that are doped with one or more p-type dopants, such as boron (B), gallium (Ga), and/or indium (In), among other examples. The n-doped well region 1110 may include regions of the substrate 1102 that are doped with one or more n-type dopants, such as phosphorous (P), arsenic (As), bismuth (Bi), and/or antimony (Sb), among other examples. The p+ regions 1108 (e.g., p-type regions) may be regions of the substrate 1102 that are doped with one or more p-type dopants, such as boron (B), gallium (Ga), and/or indium (In), among other examples. The n+ regions 1112 (e.g., n-type regions) may be regions of the substrate 1102 that are doped with one or more n-type dopants, such as phosphorous (P), arsenic (As), bismuth (Bi), and/or antimony (Sb), among other examples. The deep n-well barrier region 1114 may be a region of the substrate 1102 that is doped with one or more n-type dopants. The dopant concentration in the p+ regions 1108 may be greater than the dopant concentration in the p-doped well region 1106. The dopant concentration in the n+ regions 1112 may be greater than the dopant concentration in the n-doped well region 1110.

The n-doped well region 1110 connects to the deep n-well barrier region 1114 to provide bias for the deep n-well barrier region 1114. The p-doped well region 1106 connects to substrate 1102.

As indicated above, FIG. 11 is provided as an example. Other examples may differ from what is described with regard to FIG. 11.

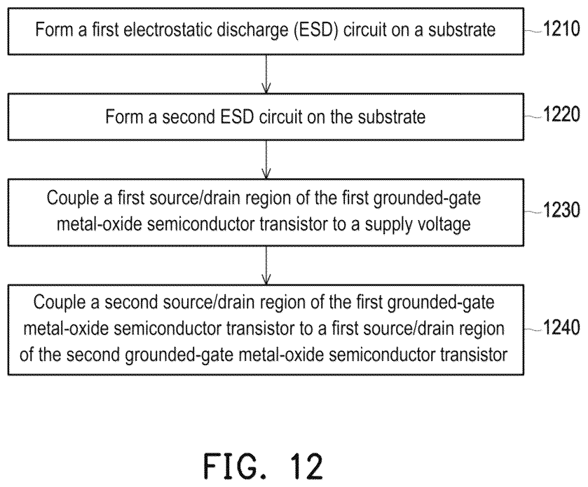

FIG. 12 is a flowchart of an example process 1200 associated with forming a semiconductor device. In some implementations, one or more process blocks of FIG. 12 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 12, process 1200 may include forming a first electrostatic discharge (ESD) circuit on a substrate (block 1210). For example, one or more semiconductor processing tools may be used to form a first electrostatic discharge (ESD) circuit (e.g., ESD protection circuit 102, 502, 802, 902) on a substrate (e.g., substrate 132, 522), as described herein. In some implementations, the first ESD circuit includes a first grounded-gate metal-oxide semiconductor transistor (e.g., ggNMOS transistor 116, 510, 812, 914, 918).

As further shown in FIG. 12, process 1200 may include forming a second ESD circuit on the substrate (block 1220). For example, one or more semiconductor processing tools may be used to form a second ESD circuit ((e.g., ESD protection circuit 104, 504, 804, 904) on the substrate, as described herein. In some implementations, the second ESD circuit includes a second grounded-gate metal-oxide semiconductor transistor (e.g., ggNMOS transistor 116, 510, 812, 914, 918).

As further shown in FIG. 12, process 1200 may include coupling a first source/drain region of the first grounded-gate metal-oxide semiconductor transistor to a supply voltage (block 1230). For example, one or more semiconductor processing tools may be used to couple a first source/drain region of the first grounded-gate metal-oxide semiconductor transistor to a supply voltage (e.g., supply voltage source 122, 512, 816, 928), as described herein.

As further shown in FIG. 12, process 1200 may include coupling a second source/drain region of the first grounded-gate metal-oxide semiconductor transistor to a first source/drain region of the second grounded-gate metal-oxide semiconductor transistor (block 1240). For example, one or more semiconductor processing tools may be used to couple a second source/drain region of the first grounded-gate metal-oxide semiconductor transistor to a first source/drain region of the second grounded-gate metal-oxide semiconductor transistor, as described herein. In some implementations, the first grounded-gate metal-oxide semiconductor transistor and the second grounded-gate metal-oxide semiconductor transistor have a same doping type.

Process 1200 may include additional implementations, such as any single implementation or any combination of implementations described below and/or in connection with one or more other processes described elsewhere herein.

In a first implementation, process 1200 includes forming a third ESD circuit (e.g., ESD protection circuit 106, 506, 806, 906) on the substrate, where the third ESD circuit includes a third grounded-gate metal-oxide semiconductor transistor (e.g., ggNMOS transistor 116, 510, 812, 914, 918), and coupling a second source/drain region of the second grounded-gate metal-oxide semiconductor transistor to a first source/drain region of the third grounded-gate metal-oxide semiconductor transistor.

In a second implementation, process 1200 includes coupling a second source/drain region of the third grounded-gate metal-oxide semiconductor transistor to a ground voltage (e.g. ground voltage source 128, 518, 822, 934).

In a third implementation, process 1200 includes forming a back-to-back (B2B) diode structure (e.g., B2B diode structure 402, 702) between the first ESD circuit and the second ESD circuit, where the B2B diode structure includes a first diode (e.g., first diode 406, 706) arranged in a first direction, and a second diode (e.g., second diode 408, 708) arranged in a second direction opposite the first direction, and where the second source/drain region of the first grounded-gate metal-oxide semiconductor transistor is coupled to the first source/drain region of the second grounded-gate metal-oxide semiconductor transistor through the second diode.

Although FIG. 12 shows example blocks of process 1200, in some implementations, process 1200 includes additional blocks, fewer blocks, different blocks, or differently arranged blocks than those depicted in FIG. 12. Additionally, or alternatively, two or more of the blocks of process 1200 may be performed in parallel.

In this way, a semiconductor device includes an ESD protection device that includes multiple stacked middle voltage and/or low voltage ESD protection circuits including transistors with thinner gate dielectric layers and correspondingly lower threshold voltages than the gate dielectric layers and threshold voltages of the high voltage ESD protection circuits. Due to their thinner gate dielectric layers and correspondingly lower threshold voltages, transistors in the middle and/or low voltage ESD protection circuits, including transistors with large active region width values, may fully turn on in response to the short (e.g., ~1 nanosecond) CDM pulses. Combined bias voltages of multiple interconnected middle voltage and/or low voltage circuits in a stacked arrangement permits use of the stacked arrangement for high voltage applications. In some cases, the number of middle voltage and/or low voltage circuits can vary based on required bias voltages. In addition, B2B diodes between middle voltage and/or low voltage circuits may provide additional bias voltages. As a result, an ESD protection device that includes multiple stacked middle voltage and/or low voltage circuits may fully dissipate CDM current, leading to improved performance and adequate responses to ESD events.

As described in greater detail above, some implementations described herein provide a semiconductor device. The semiconductor device includes a plurality of electrostatic discharge (ESD) circuits in a stacked arrangement, where the plurality of ESD circuits are connected to each other and connected between a first voltage and a second voltage different from the first voltage, where respective ESD circuits of the plurality of ESD circuits include one or more grounded-gate metal-oxide semiconductor transistors, and where a voltage output portion of an ESD circuit of the plurality of ESD circuits is coupled to a voltage input portion of an adjacent ESD circuit of the plurality of ESD circuits.

As described in greater detail above, some implementations described herein provide a method. The method includes forming a first electrostatic discharge (ESD) circuit on a substrate, where the first ESD circuit includes a first grounded-gate metal-oxide semiconductor transistor. The method includes forming a second ESD circuit on the substrate, where the second ESD circuit includes a second grounded-gate metal-oxide semiconductor transistor. The method includes coupling a first source/drain region of the first grounded-gate metal-oxide semiconductor transistor to a supply voltage. The method includes coupling a second source/drain region of the first grounded-gate metal-oxide semiconductor transistor to a first source/drain region of the second grounded-gate metal-oxide semiconductor transistor, where the first grounded-gate metal-oxide semiconductor transistor and the second grounded-gate metal-oxide semiconductor transistor have a same doping type.

As described in greater detail above, some implementations described herein provide a semiconductor device. The semiconductor device includes a plurality of interconnected electrostatic discharge (ESD) circuits on a substrate, where a first ESD circuit of the plurality of interconnected ESD circuits is electrically connected to a second ESD circuit of the plurality of interconnected ESD circuits, where the second ESD circuit of the plurality of interconnected ESD circuits is electrically connected to a third ESD circuit of the plurality of interconnected ESD circuits, where each of the first ESD circuit, the second ESD circuit, and the third ESD circuit includes a grounded-gate metal-oxide semiconductor transistor, and where each of the first ESD circuit, the second ESD circuit, and the third ESD circuit has approximately a same bias voltage.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a plurality of electrostatic discharge (ESD) circuits in a stacked arrangement,
wherein the plurality of ESD circuits are connected to each other and connected between a first voltage and a second voltage different from the first voltage,
wherein respective ESD circuits of the plurality of ESD circuits comprise one or more grounded-gate metal-oxide semiconductor transistors, and
wherein a voltage output portion of an ESD circuit of the plurality of ESD circuits is coupled to a voltage input portion of an adjacent ESD circuit of the plurality of ESD circuits.

2. The semiconductor device of claim 1, wherein the plurality of ESD circuits comprises a plurality of clamp circuits.

3. The semiconductor device of claim 2, wherein each of the respective ESD circuits of the plurality of ESD circuits further comprises:
a p-type metal-oxide semiconductor (PMOS) transistor;
a first n-type metal-oxide semiconductor (NMOS) transistor;
a capacitor coupled to a gate of the PMOS transistor and to a gate of the first NMOS transistor; and
a second NMOS transistor,
wherein a gate of the second NMOS transistor is coupled to a source/drain region of the PMOS transistor, and to a source/drain region of the first NMOS transistor.

4. The semiconductor device of claim 3, wherein a source/drain region of a first NMOS transistor of a first ESD circuit of the plurality of ESD circuits is coupled to a source/drain region of a PMOS transistor of a second ESD circuit of the plurality of ESD circuits.

5. The semiconductor device of claim 3, wherein a source/drain region of a second NMOS transistor of a first ESD circuit of the plurality of ESD circuits is coupled to a source/drain region of a second NMOS transistor of a second ESD circuit of the plurality of ESD circuits.

6. The semiconductor device of claim 5, wherein the second NMOS transistor of the first ESD circuit and the second NMOS transistor of a second ESD circuit are each a grounded-gate metal-oxide semiconductor transistor.

7. The semiconductor device of claim 1, wherein the respective ESD circuits of the plurality of ESD circuits each comprise a grounded-gate n-type metal-oxide semiconductor (ggNMOS) transistor.

8. The semiconductor device of claim 7, wherein a source/drain region of a ggNMOS transistor of a first ESD circuit of the plurality of ESD circuits is coupled to a source/drain region of a ggNMOS transistor of a second ESD circuit of the plurality of ESD circuits.

9. The semiconductor device of claim 1, further comprising a back-to-back (B2B) diode structure between adjacent ESD circuits of the plurality of ESD circuits.

10. The semiconductor device of claim 9, wherein a first diode of the B2B diode structure conducts current in a first direction, and
wherein a second diode of the B2B diode structure conducts current in a second direction opposite the first direction.

11. The semiconductor device of claim 1, further comprising one or more isolation structures disposed around the respective ESD circuits of the plurality of ESD circuits,
wherein the one or more isolation structures comprise one or more doped wells in a semiconductor substrate.

12. A method, comprising:
forming a first electrostatic discharge (ESD) circuit on a substrate,
wherein the first ESD circuit comprises a first grounded-gate metal-oxide semiconductor transistor;
forming a second ESD circuit on the substrate,
wherein the second ESD circuit comprises a second grounded-gate metal-oxide semiconductor transistor;
coupling a first source/drain region of the first grounded-gate metal-oxide semiconductor transistor to a supply voltage; and
coupling a second source/drain region of the first grounded-gate metal-oxide semiconductor transistor to a first source/drain region of the second grounded-gate metal-oxide semiconductor transistor,
wherein the first grounded-gate metal-oxide semiconductor transistor and the second grounded-gate metal-oxide semiconductor transistor have a same doping type.

13. The method of claim 12, further comprising:
forming a third ESD circuit on the substrate,
wherein the third ESD circuit comprises a third grounded-gate metal-oxide semiconductor transistor; and
coupling a second source/drain region of the second grounded-gate metal-oxide semiconductor transistor to a first source/drain region of the third grounded-gate metal-oxide semiconductor transistor.

14. The method of claim 13, further comprising coupling a second source/drain region of the third grounded-gate metal-oxide semiconductor transistor to a ground voltage.

15. The method of claim 12, further comprising:
forming a back-to-back (B2B) diode structure between the first ESD circuit and the second ESD circuit,
wherein the B2B diode structure comprises a first diode arranged in a first direction, and a second diode arranged in a second direction opposite the first direction, and
wherein the second source/drain region of the first grounded-gate metal-oxide semiconductor transistor is coupled to the first source/drain region of the second grounded-gate metal-oxide semiconductor transistor through the second diode.

16. A semiconductor device, comprising:
a plurality of interconnected electrostatic discharge (ESD) circuits on a substrate,
wherein a first ESD circuit of the plurality of interconnected ESD circuits is electrically connected to a second ESD circuit of the plurality of interconnected ESD circuits,
wherein the second ESD circuit of the plurality of interconnected ESD circuits is electrically connected to a third ESD circuit of the plurality of interconnected ESD circuits,
wherein each of the first ESD circuit, the second ESD circuit, and the third ESD circuit comprises a grounded-gate metal-oxide semiconductor transistor, and
wherein each of the first ESD circuit, the second ESD circuit, and the third ESD circuit has approximately a same bias voltage.

17. The semiconductor device of claim 16, wherein the third ESD circuit of the plurality of interconnected ESD circuits is electrically connected to a fourth ESD circuit of the plurality of interconnected ESD circuits, and
wherein the fourth ESD circuit has a smaller bias voltage than bias voltages of each of the first ESD circuit, the second ESD circuit, and the third ESD circuit.

18. The semiconductor device of claim 17, wherein the first ESD circuit is connected to a supply voltage, and
wherein the fourth ESD circuit is connected to a ground voltage.

19. The semiconductor device of claim 16, further comprising:
a first back-to-back (B2B) diode structure comprising a first pair of diodes connected between the first ESD circuit and the second ESD circuit; and
a second B2B diode structure comprising a second pair of diodes connected between the second ESD circuit and the third ESD circuit.

20. The semiconductor device of claim 19, wherein each of the first pair of diodes and the second pair of diodes has a smaller bias voltage than bias voltages of each of the first ESD circuit, the second ESD circuit, and the third ESD circuit.
